(19) United States
(12) Patent Application Publication
(10) Pub. No.: US 2026/0371894 A1
(43) Pub. Date: Nov. 19, 2026

(54) DISPLAY DEVICE INCLUDING LIGHT EMITTING ELEMENTS HAVING RECESSES AND ELECTRONIC DEVICE INCLUDING THE SAME

(71) Applicant: SAMSUNG DISPLAY CO., LTD., YONGIN-SI (KR)

(72) Inventors: Seung Bae KANG, Yongin-si (KR); Hee Sung YANG, Yongin-si (KR); Woo Jin CHO, Yongin-si (KR)

(21) Appl. No.: 19/434,198

(22) Filed: Dec. 29, 2025

(30) Foreign Application Priority Data
May 14, 2025 (KR) 10-2025-0062485

(51) Int. Cl. H10K 59/80; H10K 59/12; H10K 59/122; H10K 59/38

(52) U.S. Cl. CPC H10K 59/80515; H10K 59/1201; H10K 59/122; H10K 59/38; H10K 59/80521; H10K 59/873

(57) ABSTRACT

A display device includes a substrate, a plurality of thin-film transistors disposed on the substrate, an organic layer disposed on the plurality of thin-film transistors, a plurality of light-emitting elements disposed on the organic layer and emitting light, an encapsulation layer disposed on the plurality of light-emitting elements, a color filter layer disposed on the encapsulation layer and transmitting light in a particular wavelength range. Each of the plurality of light-emitting elements includes a first electrode disposed on the organic layer, an emissive layer disposed on the first electrode, and a second electrode disposed on the emissive layer. An upper surface of the first electrode includes a plurality of convex first recessed portions, and a first flat portion disposed between the first recessed portions, and wherein a width of each of the plurality of first recessed portions is equal to or less than 60 nm.

This U.S. non-provisional patent application claims priority under 35 U.S.C. § 119 to Korean Patent Application No. 10-2025-0062485, filed on May 14, 2025, the disclosure of which is herein incorporated by reference in its entirety.

### TECHNICAL FIELD

The present disclosure relates to a display device and, more specifically, to a display device including light emitting elements having recesses and an electronic device including the same.

### DISCUSSION OF THE RELATED ART

As the information-oriented society evolves, the demand for display devices is ever increasing. Display devices may be flat panel display devices such as a liquid-crystal display device, a field emission display device, and a light-emitting display device. Light-emitting display devices may include an organic light-emitting display device including an organic light-emitting element, an inorganic light-emitting display device including an inorganic light-emitting element such as an inorganic semiconductor, and a micro-light-emitting display device including an ultra-small light-emitting element.

An organic light-emitting display device including organic light-emitting elements requires no separate light source such as a backlight unit, and thus it consumes less power and can be made light and thin. Such display devices may also exhibit high-quality characteristics such as wide viewing angle, high luminance and contrast, and fast response speed. Accordingly, organic light-emitting display devices have attracted attention as next generation display devices.

An organic light-emitting display device may include a polarizing plate to prevent degradation of visibility due to reflection of external light. Unfortunately, such a polarizing plate may lower the light output ratio of light emitted from an organic light-emitting element. By employing a color filter instead of a polarizing plate, the light output ratio of light emitted from the organic light-emitting element can be increased. However, in an off-state of a display device when no image is displayed, an asymmetrical color spreading (or asymmetrical color separation) phenomenon may occur, i.e., a given color may look different between one end of the reflected light reflected in the display device and the opposite end.

### SUMMARY

A display device includes a substrate, a plurality of thin-film transistors disposed on the substrate, an organic layer disposed on the plurality of thin-film transistors, a plurality of light-emitting elements disposed on the organic layer and configured to emit light, an encapsulation layer disposed on the plurality of light-emitting elements, a color filter layer disposed on the encapsulation layer and configured to transmit light in a particular wavelength range. Each of the plurality of light-emitting elements includes a first electrode disposed on the organic layer, an emissive layer disposed on the first electrode, and a second electrode disposed on the emissive layer. An upper surface of the first electrode includes a plurality of first recessed portions, and a first flat portion is disposed between the first recessed portions. Each of the plurality of first recessed portions has a concave shape with respect to the upper surface of the first electrode. A width of each of the plurality of first recessed portions is equal to or less than 60 nm.

A plurality of second recessed portions may be disposed on an entire upper surface of the organic layer. Each of the plurality of second recessed portions has a concave shape with respect to the upper surface of the organic layer. Some of the plurality of second recessed portions may overlap with the plurality of light-emitting elements, while the others might not overlap with the plurality of light-emitting elements.

A lower surface of the first electrode may include a plurality of second recessed portions concave with respect to the lower surface of the first electrode, and a second flat portion disposed between the plurality of second recessed portions.

Each of the second recessed portions may overlap with a respective one of the first recessed portions in a thickness direction of the substrate, and wherein a width of each of the second recessed portions may be equal to a width of the respective one of the first recessed portions.

An upper surface of the emissive layer may include a plurality of third recessed portions that are each concave with respect to the upper surface of the emissive layer, and a third flat portion disposed between the plurality of third recessed portions.

Each of the third recessed portions may overlap with a respective one of the first recessed portions in a thickness direction of the substrate, and a width of each of the third recessed portions may be equal to a width of the respective one of the first recessed portions.

An upper surface of the second electrode may include a plurality of fourth recessed portions that each have a concave shape with respect to the upper surface of the second electrode, and a fourth flat portion disposed between the plurality of fourth recessed portions.

Each of the fourth recessed portions may overlap with a respective one of the first recessed portions in a thickness direction of the substrate, and a width of each of the fourth recessed portions may be equal to a width of the respective one of the first recessed portions.

An upper surface of the encapsulation layer may include a plurality of fifth recessed portions that has a concave shape with respect to the upper surface of the encapsulation layer, and a fifth flat portion disposed between the plurality of fifth recessed portions.

Each of the fifth recessed portions may overlap with a respective one of the fifth recessed portions in a thickness direction of the substrate, and a width of each of the fifth recessed portions may be equal to a width of the respective one of the fifth recessed portions.

An area of the plurality of first recessed portions disposed in each of the plurality of light-emitting elements may occupy 75% or more of an area of respective emission areas.

A method for fabricating a display device includes forming a plurality of thin-film transistors on a substrate, and forming an organic layer on the plurality of thin-film transistors. A metal layer is deposited to entirely cover the organic layer on the organic layer. The metal layer is heat treated and agglomerated to form a plurality of metal grains that are spaced apart from one another. A mask layer is deposited on the plurality of metal grains and the organic layer so as to cover the plurality of metal grains. The plurality of metal grains and the mask layer positioned on the plurality of metal grains are removed, leaving the mask layer positioned between the plurality of metal grains. The organic layer that is exposed and not covered by the mask layer is ashed to form a plurality of first recessed portions. Each of the plurality of first recessed portions has a concave shape with respect to the upper surface of the organic layer. The mask layer is removed, forming a plurality of pixel electrodes that are spaced apart from one another on the organic layer. A pixel-defining layer is formed covering an edge of each of the plurality of pixel electrodes. An emissive layer is formed on each of the plurality of pixel electrodes exposed without being covered by the pixel-defining layer. A common electrode is formed on the emissive layer and the pixel-defining layer. An encapsulation layer is formed on the common electrode.

The pixel electrodes may be disposed on the first recessed portions of the organic layer, and an upper surface of each of the plurality of pixel electrodes may include a plurality of second recessed portions and a second flat portion positioned between the plurality of second recessed portions. Each of the plurality of second recessed portions has a concave shape with respect to the upper surface of the plurality of pixel electrodes.

Each of the second recessed portions may overlap with a respective one of the first recessed portions in a thickness direction of the substrate, and a width of each of the second recessed portions may be equal to a width of the respective one of the first recessed portions.

The metal layer and the metal grains may include silver (Ag).

A thickness of the metal layer may range from 2.5 nm to 5 nm.

The mask layer may include conductive oxide, and a thickness of the mask layer may be smaller than a size of the metal grains.

A size of each of the plurality of first recessed portions may be equal to the size of a respective one of the plurality of metal grains at a same position.

An electronic device includes a display module for displaying an image, and a processor for transmitting an image data signal to the display module. The display module includes a substrate, a plurality of thin-film transistors disposed on the substrate, an organic layer disposed on the plurality of thin-film transistors, a plurality of light-emitting elements disposed on the organic layer and emitting light, an encapsulation layer disposed on the plurality of light-emitting elements, a color filter layer disposed on the encapsulation layer and transmitting light in a particular wavelength range. Each of the plurality of light-emitting elements includes a first electrode disposed on the organic layer, an emissive layer disposed on the first electrode, and a second electrode disposed on the emissive layer. An upper surface of the first electrode includes a plurality of first recessed portions, and a first flat portion disposed between the first recessed portions. Each of the plurality of first recessed portions has a concave shape with respect to the upper surface of the first electrode. A width of each of the plurality of first recessed portions is equal to or less than 60 nm.

A lower surface of the first electrode may include a plurality of second recessed portions, and a second flat portion disposed between the plurality of second recessed portions. Each of the plurality of second recessed portions having a concave shape with respect to the lower surface of the first electrode.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view of a display device according to an embodiment of the present disclosure.

FIG. 2 is a side view showing the display device according to the embodiment of the present disclosure.

FIG. 3 is a layout diagram schematically showing an example of the touch sensing layer of FIG. 2.

FIG. 4 is an enlarged view of area A1 shown in FIG. 3.

FIG. 5 is an enlarged view of area PX shown in FIG. 4.

FIG. 6 is a cross-sectional view showing an example of the display panel, taken along line X1-X1′ of FIG. 5.

FIG. 7 is an enlarged, cross-sectional view showing in detail an example of area A of FIG. 6.

FIG. 8 is an enlarged plan view showing recess portions and a flat portion in an emission area of area A3 according to the embodiment.

FIG. 9 is a flowchart for illustrating processing steps of fabricating a display device according to an embodiment of the present disclosure.

FIGS. 10, 11, 12, 13, 14, 15, 16, 17, 18, 19, and 20 are cross-sectional views showing processing steps of fabricating a display device according to an embodiment of the present disclosure.

FIG. 21 is a block diagram of an electronic device according to an embodiment of the present disclosure.

FIG. 22 is a view showing various electronic devices according to a variety of embodiments of the present disclosure.

### DETAILED DESCRIPTION OF THE EMBODIMENTS

Embodiments of the present disclosure will be described more fully hereinafter with reference to the accompanying drawings. Like reference numerals may refer to like elements throughout the specification and the accompanying drawings.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationship between components should be interpreted in a like fashion.

It will be understood that when a component, such as a film, a region, a layer, or an element, is referred to as being “on”, “connected to”, “coupled to”, or “adjacent to” another component, it can be directly on, connected, coupled, or adjacent to the other component, or intervening components may be present. It will also be understood that when a component is referred to as “covering” another component, it can be the only component covering the other component, or one or more intervening components may also be covering the other component. Other words used to describe the relationship between elements may be interpreted in a like fashion.

It will be further understood that descriptions of features or aspects within each embodiment are available for other similar features or aspects in other embodiments, unless the context clearly indicates otherwise. Accordingly, all features and structures described herein may be mixed and matched in any desirable manner.

As used herein, the singular forms “a”, “an” and “the” are intended to include the plural forms as well, unless the context clearly indicates otherwise.

When a feature is said to extend, protrude, or otherwise follow a certain direction, it will be understood that the feature may follow said direction in the negative, i.e., opposite direction. Accordingly, the feature is not necessarily limited to follow exactly one direction, and may follow along an axis formed by the direction, unless the context clearly indicates otherwise.

Hereinafter, exemplary embodiments of the present disclosure will be described in detail with reference to the accompanying drawings.

Embodiments of the present disclosure relate to a light-emitting display device, such as an organic light-emitting diode (OLED) display, designed to prevent asymmetrical color spreading caused by uneven reflection of external light. The device includes a multilayer structure comprising a substrate supporting thin-film transistors, organic interlayers, light-emitting elements, an encapsulation layer, and a color filter layer that transmits specific wavelengths of light. Each light-emitting element has a first electrode, an emissive layer, and a second electrode, arranged so that the upper surface of the first electrode includes a pattern of nano-scale recessed portions and flat regions. These recessed portions, each 60 nanometers or less in width, are engineered to scatter incident light randomly, preventing the light from being reflected in a directional or uneven manner that could cause visible color irregularities when the display is turned off.

The structure extends through multiple layers of the emissive stack so that the recessed patterns are aligned vertically across the electrode, emissive, and encapsulation layers. This alignment ensures that reflected light encounters consistent nanoscale topography throughout the optical path, enhancing scattering uniformity and mitigating asymmetrical reflection. The design achieves an aesthetically uniform dark appearance when the display is off, even without a polarizing plate. As a result, the device maintains higher light output efficiency while reducing manufacturing complexity and cost. Embodiments of the present disclosure also integrate a touch sensing layer and color filters above the emissive structure, allowing for improved anti-reflective performance without sacrificing brightness or color fidelity.

The disclosed fabrication method involves depositing a thin metal layer, typically silver, on an organic surface, then heat-treating it to form discrete nano-sized metal grains. A mask layer is applied over the grains, and selective removal followed by etching transfers the grain pattern into the underlying organic layer as concave recesses. Pixel electrodes are then deposited on this textured surface, reproducing the pattern as concave recesses on their underside and concave recesses on their top. These nano-patterned surfaces propagate through subsequent emissive and encapsulation layers, forming a continuous optical diffusion structure. The result is a display that delivers both functional and visual benefits, reducing asymmetric reflection, enhancing contrast, and preserving color uniformity under ambient light.

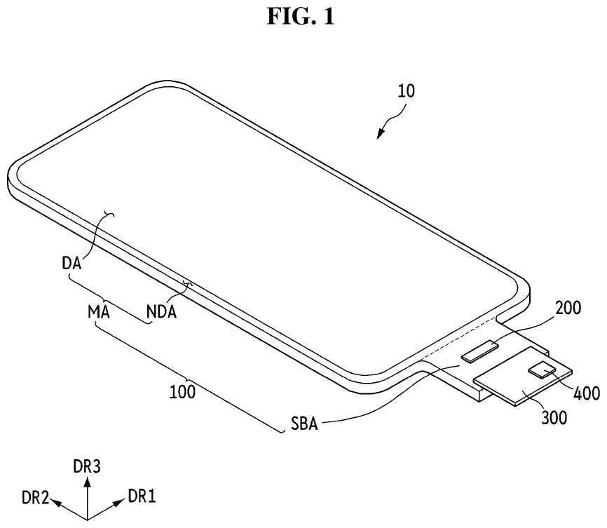

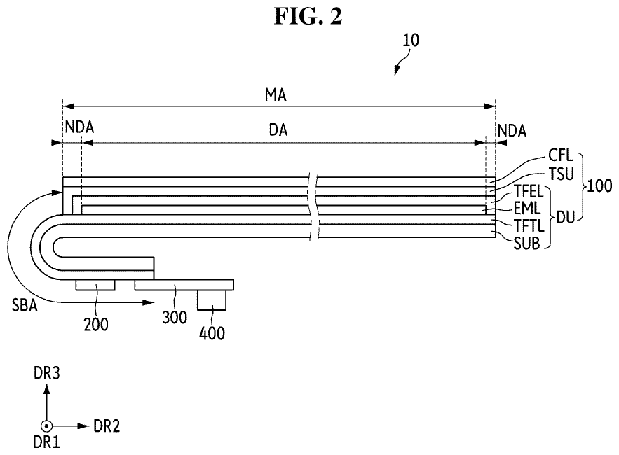

FIG. 1 is a perspective view of a display device according to an embodiment of the present disclosure. FIG. 2 is a side view showing the display device according to the embodiment of the present disclosure.

Referring to FIGS. 1 and 2, a display device 10, according to the embodiment of the present disclosure may be employed by portable electronic devices such as a mobile phone, a smart phone, a tablet computer, a mobile communications terminal, an electronic notebook, an electronic book, a portable multimedia player (PMP), a navigation device, and an ultra mobile PC (UMPC). Alternatively, the display device 10, according to the embodiment of the present disclosure, may be used as a display unit of a television, a laptop/notebook computer, a computer monitor, an electronic billboard, or an Internet of Things (IOT) device. Alternatively, the display device 10, according to the embodiment of the present disclosure, may be applied to wearable devices such as a smart watch, a watch phone, a glasses-type display, and a head-mounted display (HMD) device. Alternatively, the display device 10, according to the embodiment, may be used as a center information display (CID) placed at the instrument cluster, the center fascia or the dashboard of a vehicle, and as a display placed on the back of each of the front seats that is an entertainment system for passengers at the rear seats of a vehicle.

The display device 10 may be a light-emitting display device such as an organic light-emitting display device using organic light-emitting diodes, a quantum-dot light-emitting display device including a quantum-dot emissive layer, an inorganic light-emitting display device including an inorganic semiconductor, and a micro light-emitting display device using micro or nano light-emitting diodes (micro LEDs or nano LEDs). In the following description, an organic light-emitting display device is described as an example of the display device 10. It is, however, to be understood that the present disclosure is not necessarily limited thereto.

The display device 10 includes a display panel 100, a display driver circuit 200, a display circuit board 300 and a touch driver circuit 400.

The display panel 100 may be formed in a rectangular plane having a pair of shorter sides extending in the first direction DR1 and a pair of longer sides extending in the second direction DR2 intersecting the first direction DR1. Each of the corners where the shorter side in the first direction DR1 meets the longer side in the second direction DR2 may be rounded with a curvature or may be a right angle. The shape of the display panel 100 when viewed from the top is not necessarily limited to a quadrilateral shape, but may be formed in a different polygonal shape, a circular shape, or an elliptical shape. The display panel 100 may be formed flat, but the present disclosure is not necessarily limited thereto. For example, the display panel 100 includes curved portions formed at left and right ends and having a constant curvature or a varying curvature. In addition, the display panel 100 may be flexible so that it can be curved, bent, folded or rolled to at least a noticeable extent without cracking or otherwise sustaining damage thereto.

The display panel 100 includes a main area MA and a subsidiary area SBA.

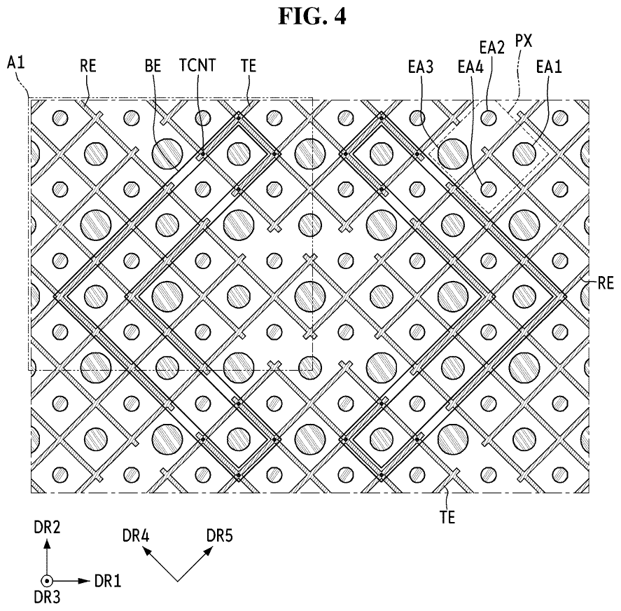

The main area MA includes a display area DA where images are displayed, and a non-display area NDA around the display area DA. The display area DA includes pixels PX (see FIG. 4) for displaying images. The subsidiary area SBA may protrude from one side of the main area MA in the second direction DR2.

Although the subsidiary area SBA is unfolded in the example shown in FIG. 1, the subsidiary area SBA may be bent and may be disposed on the lower surface of the display panel 100 as shown in FIG. 2. When the subsidiary area SBA is bent, it may overlap the main area MA in a third direction DR3 of the substrate SUB which is the thickness direction. The display driver circuit 200 may be disposed in the subsidiary area SBA.

As shown in FIG. 2, the display panel 100 may include a display layer DU, a touch sensing layer TSU, and a color filter layer CFL. The display layer DU may include a substrate SUB, a thin-film transistor layer TFTL, an emission material layer EML and an encapsulation layer TFEL.

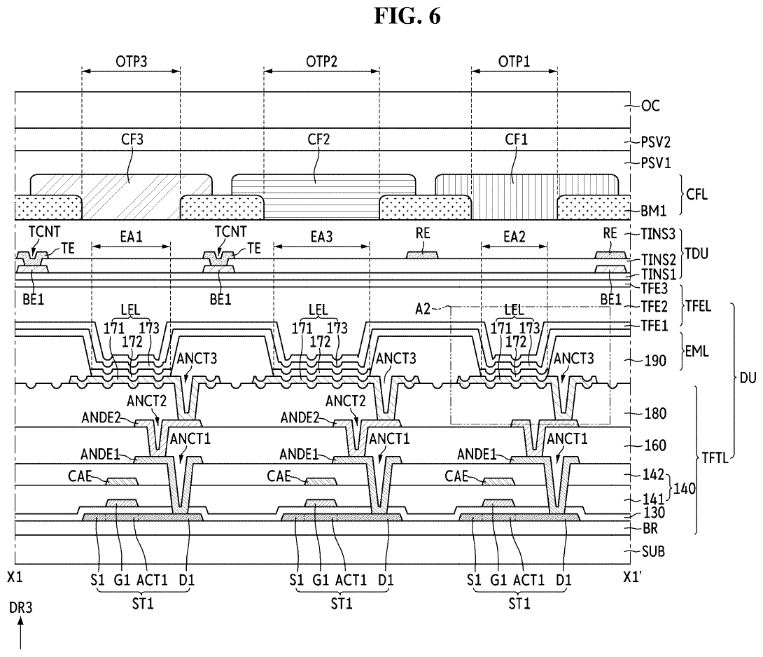

The thin-film transistor layer TFTL may be disposed on the substrate SUB. The thin-film transistor layer TFTL may be placed in the main area MA and the subsidiary area SBA. The thin-film transistor layer TFTL includes transistors ST1 (see FIG. 6).

The emission material layer EML may be disposed on the thin-film transistor layer TFTL. The emission material layer EML may be disposed in the display area DA of the main area MA. The emission material layer EML includes light-emitting elements disposed in emission areas.

The encapsulation layer TFEL may be disposed on the emission material layer EML. The encapsulation layer TFEL may be disposed in the display area DA and the non-display area NDA of the main area MA. The encapsulation layer TFEL includes at least one inorganic film and at least one organic film for encapsulating the emission material layer.

The touch sensing layer TSU may be disposed on the encapsulation layer TFEL. The touch sensing layer TSU may be disposed in the display area DA and the non-display area NDA of the main area MA. The touch sensing layer TSU may sense a touch of a person or an object using sensor electrodes.

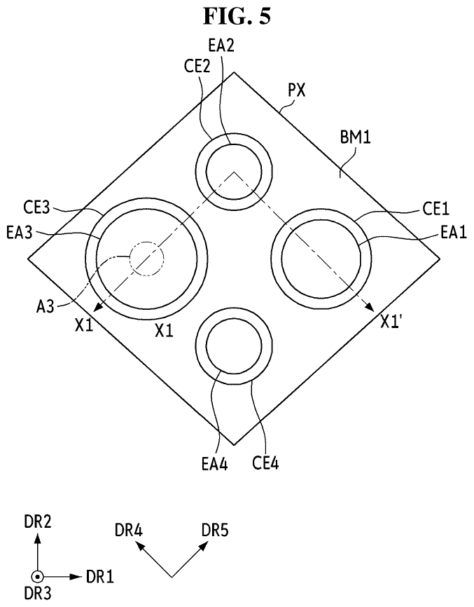

The color filter layer CFL may be disposed on the touch sensing unit TSU. The color filter layer CFL may be disposed in the display area DA and the non-display area NDA of the main area MA. The color filter layer CFL may be an anti-reflection element for reducing reflection of external light from metal lines and metal electrodes of the display panel 100. The color filter layer CFL includes a plurality of color filters. For example, the color filter layer CFL includes a first color filter CF1 (see FIG. 5) that transmits light in a first wavelength range, a second color filter CF2 (see FIG. 5) that transmits light in a second wavelength range, a third color filter CF3 (see FIG. 5) that transmits light in a third wavelength range, and a fourth color filter CF4 (see FIG. 5) that transmits light in a fourth wavelength range.

A cover window for protecting the display panel 100 from above may be disposed on the color filter layer CFL. The cover window may be attached on the color filter layer CFL by a transparent adhesive such as an optically clear adhesive (OCA) film and an optically clear resin (OCR). The cover window may include an inorganic material such as glass, or an organic material such as plastic and polymer material.

The display driver circuit 200 may generate signals and voltages for driving the display panel 100. The display driver circuit 200 may be implemented as an integrated circuit (IC) and may be attached to the display panel 100 by a chip on glass (COG) technique, a chip on plastic (COP) technique, or an ultrasonic bonding. It is, however, to be understood that the present disclosure is not necessarily limited thereto. For example, the display driver circuit 200 may be attached on the display circuit board 300 by the chip-on-film (COF) technique.

The display circuit board 300 may be attached to one end of the subsidiary area SBA of the display panel 100. Accordingly, the display circuit board 300 may be electrically connected to the display panel 100 and the display driver circuit 200. The display panel 100 and the display driver circuit 200 may receive digital video data, timing signals, and driving voltages through the display circuit board 300. The display circuit board 300 may be a flexible printed circuit board, a printed circuit board, or a flexible film such as a chip on film.

The touch driver circuit 400 may be disposed on the display circuit board 300. The touch driver circuit 400 may be implemented as an integrated circuit (IC) and may be attached on the display circuit board 300.

The touch driver circuit 400 may be electrically connected to sensor electrodes of the touch sensing unit TSU of the display panel 100. The touch driver circuit 400 applies driving signals to the sensor electrodes of the touch sensing layer TSU and measures mutual capacitances of the sensor electrodes. The driving signals may have driving pulses. The touch driver circuit 400 can determine whether a user has touched or the presence of nearby object based on the mutual capacitances. A user's touch refers to that an object such as the user's finger or a stylus/pen is brought into contact with a surface of the display device 10 disposed on the touch sensing layer TSU. The user's near proximity refers to that an object such as the user's finger and a stylus/pen is hovering over a surface of the display device 10.

As shown in FIGS. 1 and 2, in order to reduce reflection of external light by metal lines and metal electrodes of the display panel 100, the display panel 100 includes a color filter layer CFL including color filters. Accordingly, since it is not necessary to attach a separate anti-reflection element such as a polarizing plate on the display panel 100, the fabrication cost of the display device 10 can be saved.

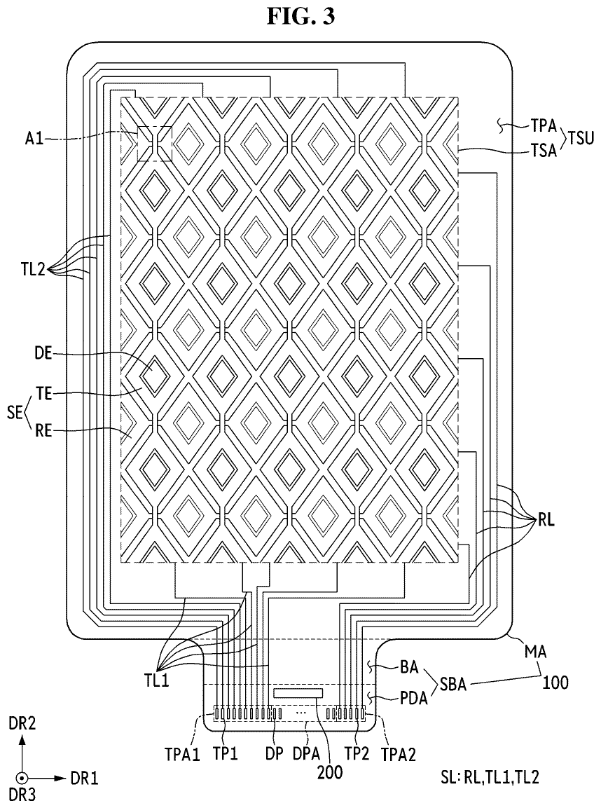

FIG. 3 is a layout diagram schematically showing an example of the touch sensing layer of FIG. 2.

In the example shown in FIG. 3, the sensor electrodes SE of the touch sensing layer TSU include two kinds of electrodes, e.g., the driving electrodes TE and the sensing electrodes RE, the mutual capacitive sensing is carried out, i.e., driving signals are applied to the driving electrodes TE and then the voltages charged at the mutual capacitances can be sensed through the sensing electrodes RE. It is, however, to be understood that the present disclosure is not necessarily limited thereto.

For convenience of illustration, FIG. 3 shows only the driving electrodes TE, the sensing electrodes RE, dummy patterns DE, sensor lines TL1, TL2 and RL, and sensor pads TP1 and TP2.

Referring to FIG. 3, the touch sensing layer TSU includes a touch sensor area TSA for sensing a user's touch, and a touch peripheral area TPA disposed around the touch sensor area TSA. The touch sensor area TSA may overlap the display area DA of FIGS. 1 and 2, and the touch peripheral area TPA may overlap the non-display area NDA of FIGS. 1 and 2.

The touch sensor area TSA includes the driving electrodes TE, the sensing electrodes RE and the dummy patterns DE. The driving electrodes TE and the sensing electrodes RE may be electrodes for forming mutual capacitance to sense a touch of an object or a person.

The sensing electrodes RE may be disposed in the first direction DR1 and second direction DR2. The sensing electrodes RE may be electrically connected with one another in the first direction DR1. The adjacent sensing electrodes RE may be connected with one another in the first direction DR1.

The driving electrodes TE may be disposed in the first direction DR1 and second direction DR2. The driving electrodes TE adjacent to one another in the first direction DR1 may be electrically separated from one another. The driving electrodes TE may be electrically connected with one another in the second direction DR2. For example, adjacent driving electrodes TE in the second direction DR2 may be connected with one another other via bridge electrodes.

Each of the dummy patterns DE may be surrounded by the driving electrode TE or the sensing electrode RE. Each of the dummy patterns DE may be electrically separated from the driving electrode TE or the sensing electrode RE. Each of the dummy patterns DE may be spaced apart from the driving electrode TE or the sensing electrode RE. Each of the dummy patterns DE may be electrically floating.

In FIG. 3, the driving electrodes TE, the sensing electrodes RE and the dummy patterns DE each have a diamond shape when viewed from the top, but the present disclosure is not necessarily limited thereto. For example, each of the driving electrodes TE, the sensing electrodes RE and the dummy patterns DE may have other quadrangular shape than a diamond, other polygonal shapes than a quadrangular shape, a circle or an ellipse when viewed from the top.

The sensor lines TL1, TL2 and RL may be disposed in the sensor peripheral area TPA. The sensor lines TL1, TL2 and RL include sensing lines RL connected to the sensing electrodes RE, and first driving lines TL1 and second driving lines TL2 connected to the driving electrodes TE.

The sensing electrodes RE disposed on one side of the touch sensor area TSA may be connected to the sensing lines RL, respectively. For example, some of the sensing electrodes RE electrically connected in the first direction DR1 that are disposed at the right end may be connected to the sensing lines RL as shown in FIG. 3. The sensing lines RL may be connected to second sensor pads TP2, respectively. Thus, the touch driver circuit 400 may be electrically connected to the sensing electrodes RE.

The driving electrodes TE disposed on one side of the touch sensor area TSA may be connected to the first driving lines TL1, respectively, while the driving electrodes TE disposed on the other side of the touch sensor area TSA may be connected to the second driving lines TL2. For example, some of the driving electrodes TE electrically connected to one another in the second direction DR2 on the lowermost side may be connected to the first driving line TL1, while some of the driving electrodes TE disposed on the uppermost side may be connected to the second driving line TL2, as shown in FIG. 3. The second driving lines TL2 may be connected to the driving electrodes TE on the upper side of the touch sensor area TSA via the left outer side of the touch sensor area TSA.

The first driving lines TL1 and the second driving lines TL2 may be connected to the first sensor pads TP1, respectively. Thus, the touch driver circuit 400 may be electrically connected to the driving electrodes TE. The driving electrodes TE are connected to the driving lines TL1 and TL2 on both sides of the touch sensor area TSA, and receive the touch driving signals. Therefore, it is possible to suppress a difference between the touch driving signals applied to the driving electrodes TE disposed on the lower side of the touch sensor area TSA which occurs due to the RC delay of the touch driving signals.

The first sensor pad area TPA1 in which the first sensor pads TP1 are disposed may be disposed on one side of the display pad area DP in which the display pads DPA are disposed. The second sensor pad area TPA2 in which the second sensor pads TP2 are disposed may be disposed on the opposite side of the display pad area DPA. The display pads DP may be electrically connected to data lines of the display panel 100.

The display pad area DPA, the first sensor pad area TPA1 and the second sensor pad area TPA2 may correspond to the pads of the display panel 100 connected to the display circuit board 300 shown in FIG. 1. The display circuit board 300 may be disposed on the display pads DP, the first sensor pads TP1, and the second sensor pads TP2. The display pads DP, the first sensor pads TP1 and the second sensor pads TP2 may be electrically connected to the display circuit board 300 using a low-resistance, high-reliability material such as an anisotropic conductive film or a sheet anisotropic paste (SAP). Therefore, the display pads DP, the first sensor pads TP1 and the second sensor pads TP2 may be electrically connected to the touch driver circuit 400 disposed on the display circuit board 300.

FIG. 4 is an enlarged view of area A1 shown in FIG. 3.

Referring to FIG. 4, the driving electrodes TE and the sensing electrodes RE are formed on the same layer and thus they may be spaced apart from each other. For example, there may be a gap between adjacent ones of the driving electrodes TE and the sensing electrodes RE.

In addition, the dummy patterns DE may also be disposed in the same layer as the driving electrodes TE and the sensing electrodes RE. For example, there may be a gap between adjacent ones of the driving electrodes TE and the dummy patterns DE and between adjacent ones of the sensing electrodes RE and the dummy patterns DE.

The bridge electrodes BE may be disposed in a different layer from the driving electrodes TE and the sensing electrodes RE. Each of the bridge electrodes BE may be bent at least once. Although the connection electrodes BE have a chevron shape such as that of angle brackets “<” or “>” in the example shown in FIG. 5, the shape of the connection electrodes BE when viewed from the top is not necessarily limited thereto. Since the driving electrodes TE adjacent to each other in the second direction DR2 are connected by the plurality of bridge electrodes BE, even if any of the bridge electrodes BE is disconnected, the driving electrodes TE can still be stably connected with each other in the second direction DR2. Although two adjacent ones of the driving electrodes TE are connected by two bridge electrodes BE in the example shown in FIG. 4, the number of bridge electrodes BE is not necessarily limited to two.

The bridge electrodes BE may overlap the driving electrodes TE adjacent to one another in the second direction DR2 in the third direction DR3, which is the thickness direction of the substrate SUB. The bridge electrodes BE may overlap the sensing electrodes RE in the third direction DR3. One side of each of the bridge electrodes BE may be connected to one of the driving electrodes TE adjacent to each other in the second direction DR2 through touch contact holes TCNT. The opposite side of each of the bridge electrodes BE may be connected to another one of the driving electrodes TE adjacent to each other in the second direction DR2 through touch contact holes TCNT.

The driving electrodes TE and the sensing electrodes RE may be electrically separated from each other at their intersections by virtue of the bridge electrodes BE. Accordingly, mutual capacitance can be formed between the driving electrodes TE and the sensing electrodes RE.

Each of the driving electrodes TE, the sensing electrodes RE and the bridge electrodes BE may have a mesh structure or a net structure when viewed from the top. In addition, each of the dummy patterns DE may have a shape of a mesh structure or a net structure when viewed from the top. Accordingly, the driving electrodes TE, the sensing electrodes RE, the bridge electrodes BE and the dummy patterns DE may be spaced apart from the emission areas EA1, EA2, EA3 and EA4 of each of the pixels PX. Therefore, it is possible to prevent the luminance of the lights output from the emission areas EA1, EA2, EA3 and EA4 from being lowered, which may occur as the lights are covered by the driving electrodes TE, the sensing electrodes RE, the bridge electrodes BE and the dummy patterns DE.

FIG. 5 is an enlarged view of area PX shown in FIG. 4.

Referring to FIG. 5, the pixel PX includes a first emission area EMA1 that emits first light, a second emission area EMA2 that emits second light, a third emission area EMA3 that emits third light, and a fourth emission area EMA4 that emits second light. For example, the first light may be light in a red wavelength range, the second light may be light in a green wavelength range, and the third light may be light in a blue wavelength range.

In each of the pixels PX, the first emission area EA1 and second emission area EA2 may be adjacent to each other in a fourth direction DR4, and the third emission area EA3 and the fourth emission area EA4 may be adjacent to each other in the fourth direction DR4. In each of the pixels PX, the first emission area EA1 and fourth emission area EA4 may be adjacent to each other in a fifth direction DR5, and the second emission area EA2 and the third emission area EA3 may be adjacent to each other in the fifth direction DR5. The fourth direction DR4 may refer to a direction between the first direction DR1 and the second direction DR2, which be inclined from the first direction DR1 by forty-five degrees. The fifth direction DR5 may be a direction perpendicular to the fourth direction DR4.

Each of the first emission area EA1, the second emission area EA2, the third emission area EA3 and the fourth emission area EA4 may have, but is not necessarily limited to, a circular shape when viewed from the top. Each of the first emission area EA1, the second emission area EA2, the third emission area EA3 and the fourth emission area EA4 may have other polygonal shapes such as a rectangular shape and a diamond shape, or an elliptical shape when viewed from the top. In addition, although the third emission area EA3 is the largest while the second emission area EA2 and the fourth emission area EA4 are the smallest in the example shown in FIG. 5, the present disclosure is not necessarily limited thereto.

The second emission areas EA2 and the fourth emission areas EA4 may be disposed in odd rows. The second emission areas EA2 and the fourth emission areas EA4 may be disposed side by side in each of the odd rows in the first direction DR1. The second emission areas EA2 and the fourth emission areas EA4 may be disposed alternately in odd rows.

The first emission areas EA1 and the third emission areas EA3 may be disposed in even rows. The first emission areas EA1 and the third emission areas EA3 may be disposed side by side in each of the even rows in the first direction DR1. The first emission areas EA1 and the third emission areas EA3 may be alternately disposed in each of the even rows.

The second emission areas EA2 and the fourth emission areas EA4 may be disposed in odd columns. The second emission areas EA2 and the fourth emission areas EA4 may be disposed side by side in each of the odd columns in the second direction DR2. The second emission areas EA2 and the fourth emission areas EA4 may be disposed alternately in each of the odd columns.

The first emission areas EA1 and the third emission areas EA3 may be disposed in even columns. The first emission areas EA1 and the third emission areas EA3 may be disposed side by side in each of the even columns in the second direction DR2. The first emission areas EA1 and the third emission areas EA3 may be alternately disposed in each of the even columns.

The color filters CF1, CF2, CF3 and CF4 may overlap with the emission areas EA1, EA2, EA3 and EA4, respectively. For example, the first color filter CF1 may overlap with the first emission area EA1 when viewed from the top. The first color filter CF1 may transmit the first light and may absorb or block the second light and the third light. Accordingly, the first light emitted in the first emission area EA1 may be output through the first color filter CF1. The second color filter CF2 may overlap with the second emission area EA2 when viewed from the top. The second color filter CF2 may transmit the second light and may absorb and block the first light and the third light. Accordingly, the second light emitted in the second emission area EA2 may be output through the second color filter CF2. The third color filter CF3 may overlap with the third emission area EA3 when viewed from the top. The third color filter CF3 may transmit the third light and may absorb and block the first light and the second light. Accordingly, the third light emitted in the third emission area EA3 may be output through the third color filter CF3. The fourth color filter CF4 may transmit the second light and may absorb and block the first light and the third light. Accordingly, the fourth light emitted in the fourth emission area EA4 may be output through the fourth color filter CF4.

The color filters CF1, CF2, CF3 and CF4 may be formed wider than the respective emission areas EA1, EA2, EA3 and EA4 so that they can entirely cover the respective emission areas EA1, EA2, EA3 and EA4.

As shown in FIGS. 4 and 5, a light-blocking layer BM1 and the sensor electrodes SE of the touch sensing layer TSU may be disposed between the emission areas EA1, EA2, EA3 and EA4. The light-blocking layer BM1 and the sensor electrodes SE may overlap each other when viewed from the top. Therefore, the light-blocking layer BM1 can prevent reflection of external light by the sensor electrodes SE. The light-blocking layer BM1 and the sensor electrodes SE can prevent that the light emission ratio is reduced because the lights output from the emission areas EA1, EA2, EA3 and EA4 of each pixel PX is blocked by the light-blocking layer BM1 or the sensor electrodes SE.

Some of the color filters CF1, CF2, CF3 and CF4 of the color filter layer CFL may overlap with the light-blocking layer BM1 and the sensor electrodes SE.

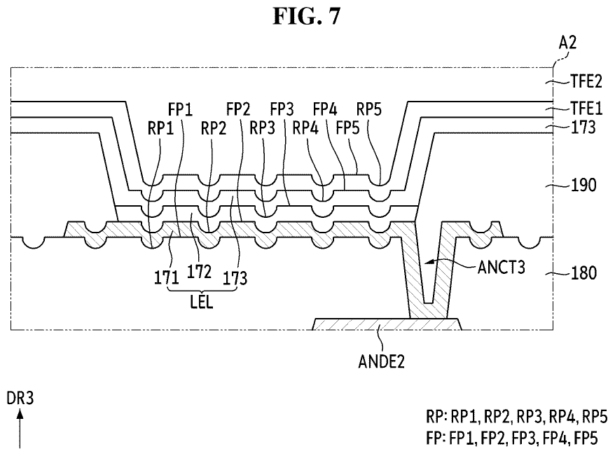

FIG. 6 is a cross-sectional view showing an example of the display panel, taken along line X1-X1′ of FIG. 5. FIG. 7 is an enlarged, cross-sectional view showing in detail an example of area A of FIG. 6.

Referring to FIGS. 6 and 7, a barrier layer BR may be placed on the substrate SUB. The substrate SUB may be a base substrate or a base element. The substrate SUB may be a flexible substrate that can be bent, folded, or rolled to at least a noticeable extent without cracking or otherwise sustaining damage thereto. For example, the substrate SUB may include, but is not necessarily limited to, a polymer resin such as polyimide PI. For another example, the substrate SUB may include a glass material or a metal material.

The barrier layer BR is a film for protecting a plurality of thin-film transistors ST1 and an emissive layer 172 of the emission material layer EML from the moisture permeating through the substrate SUB which is vulnerable to permeation of moisture. The barrier layer BR may be made up of multiple inorganic films stacked on one another alternately. For example, the barrier layer BR may be made up of multiple layers in which one or more inorganic layers of a silicon nitride layer, a silicon oxynitride layer, a silicon oxide layer, a titanium oxide layer and an aluminum oxide layer are alternately stacked on one another.

The plurality of thin-film transistors ST1 may be disposed on the barrier layer BR. Each of the thin-film transistors ST1 includes an active layer ACT1, a gate electrode G1, a source electrode S1, and a drain electrode D1.

The active layer ACT1, the source electrode S1 and the drain electrode D1 of each of the thin-film transistors ST1 may be disposed on the barrier layer BR. The active layer ACT1 of each of the thin-film transistors ST1 includes polycrystalline silicon, single crystalline silicon, low-temperature polycrystalline silicon, amorphous silicon, or an oxide semiconductor. A part of the active layer ACT1 overlapping the gate electrode G1 in the third direction DR3 that is the thickness direction of the substrate SUB may be defined as a channel region. The source electrode S1 and the drain electrode D1 are regions that do not overlap with the gate electrode G1 in the third direction DR3, and may have conductivity by doping ions or impurities into a silicon semiconductor or an oxide semiconductor.

A gate insulator 130 may be placed on the active layer ACT1, the source electrode S1 and the drain electrode D1 of the thin-film transistors ST1. The gate insulator 130 may include an inorganic layer, for example, a silicon nitride layer, a silicon oxynitride layer, a silicon oxide layer, a titanium oxide layer, or an aluminum oxide layer.

The gate electrode G1 of the thin-film transistor ST1 may be disposed on the gate insulator 130. The gate electrode G1 may overlap with the active layer ACT1 in the third direction DR3. The gate electrode G1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A first interlayer dielectric layer 141 may be placed on the gate electrode G1 of the thin-film transistor ST1 and the gate insulator 130. The first interlayer dielectric layer 141 may include an inorganic layer, for example, a silicon nitride layer, a silicon oxynitride layer, a silicon oxide layer, a titanium oxide layer, or an aluminum oxide layer. The first interlayer dielectric layer 141 may be made up of multiple inorganic films.

A capacitor electrode CAE may be placed on the first interlayer dielectric layer 141. The capacitor electrode CAE may overlap the gate electrode G1 of the thin-film transistors ST1 in the third direction DR3. Since the first interlayer dielectric layer 141 has a dielectric constant, a capacitor can be formed by the capacitor electrode CAE, the gate electrode G1, and the first interlayer dielectric layer 141 disposed between them. The capacitor electrode CAE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A second interlayer dielectric layer 142 may be placed on the capacitor electrode CAE and the first interlayer dielectric layer 141. The second interlayer dielectric layer 142 may include an inorganic layer, for example, a silicon nitride layer, a silicon oxynitride layer, a silicon oxide layer, a titanium oxide layer, or an aluminum oxide layer. The second interlayer dielectric layer 142 may be made of a plurality of inorganic films.

A first anode connection electrode ANDE1 may be placed on the second interlayer dielectric layer 142. The first anode connection electrode ANDE1 may be connected to the drain electrode D1 of the thin-film transistor ST1 through a first connection contact hole ANCT1 that penetrates the gate insulator 130, the first interlayer dielectric layer 141 and the second interlayer dielectric layer 142. The first anode connection electrode ANDE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A first organic layer 160 may be placed over the first anode connection electrode ANDE1 for providing a flat surface over the thin-film transistors ST1 having difference heights. The first organic layer 160 may be formed as an organic layer such as an acryl resin, an epoxy resin, a phenolic resin, a polyamide resin and a polyimide resin.

A second anode connection electrode ANDE2 may be disposed on the first organic layer 160. The second anode connection electrode ANDE2 may be connected to the first anode connection electrode ANDE1 through a second connection contact hole ANCT2 penetrating the first organic layer 160. The second anode connection electrode ANDE2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A second organic layer 180 may be disposed on the second anode connection electrode ANDE2. The second organic layer 180 may be formed as an organic layer such as an acryl resin, an epoxy resin, a phenolic resin, a polyamide resin and a polyimide resin.

Light-emitting elements LEL and a pixel-defining layer 190 may be disposed on the second organic layer 180. Each of the light-emitting elements LEL includes a pixel electrode 171, an emissive layer 172, and a common electrode 173.

The pixel electrode 171 may be placed on the second organic layer 180. The pixel electrode 171 may be connected to the second anode connection electrode ANDE2 through a third connection contact hole ANCT3 penetrating the second organic layer 180.

In the top-emission structure in which light exits from the emissive layer 172 toward the common electrode 173, the pixel electrode 171 may be made of a metal material having a high reflectivity such as a stack structure of aluminum and titanium (Ti/Al/Ti), a stack structure of aluminum and indium tin oxide (ITO) (ITO/Al/ITO), an APC alloy and a stack structure of APC alloy and ITO (ITO/APC/ITO). The APC alloy is an alloy of silver (Ag), palladium (Pd) and copper (Cu).

In order to define a first emission area EA1, a second emission area EA2, a third emission area EA3 and a fourth emission area EA4, the pixel-defining layer 190 may be formed to partition the pixel electrodes 171 on the second organic layer 180. The pixel-defining layer 190 may be formed to cover the edges of the pixel electrode 171. The pixel-defining layer 190 may be formed of an organic layer such as an acryl resin, an epoxy resin, a phenolic resin, a polyamide resin and a polyimide resin.

In each of the first emission area EA1, the second emission area EA2, the third emission area EA3 and the fourth emission area EA4, the pixel electrode 171, the emissive layer 172 and the common electrode 173 are stacked on one another sequentially, so that holes from the pixel electrode 171 and electrons from the common electrode 173 are combined with each other in the emissive layer 172 to emit light.

The emissive layer 172 may be disposed on the pixel electrode 171 and the pixel-defining layer 190. The emissive layer 172 may include an organic material to emit light of a particular color. For example, the emissive layer 172 may include a hole transporting layer, an organic material layer, and an electron transporting layer.

The common electrode 173 may be disposed on the emissive layer 172. The common electrode 173 may cover the emissive layer 172. The common electrode 173 may be a common layer formed commonly in the first emission area EA1, the second emission area EA2, the third emission area EA3 and the fourth emission area EA4. A capping layer may be formed on the common electrode 173.

In the top-emission organic light-emitting diode, the common electrode 173 may include a transparent conductive material (TCP) such as ITO and IZO that can transmit light, or a semi-transmissive conductive material such as an alloy of silver (Ag). When the common electrode 173 is made of a semi-transmissive metal material, the light extraction efficiency can be increased by using microcavities.

The encapsulation layer TFEL may be placed on the common electrode 173. The encapsulation layer TFEL includes at least one inorganic film to prevent permeation of oxygen or moisture into the emission material layer EML. In addition, the encapsulation layer TFEL includes at least one organic layer to protect the light-emitting element layer EML from foreign substances such as dust. For example, the encapsulation layer TFEL includes a first inorganic encapsulation film TFE1, an organic encapsulation film TFE2 and a second inorganic encapsulation layer TFE3.

The first inorganic encapsulation film TFE1 may be disposed on the common electrode 173, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation film TFE2 may be an organic film such as an acryl resin, an epoxy resin, a phenolic resin, a polyamide resin, a polyimide resin, etc.

The touch sensing unit TSU may be disposed on the encapsulation layer TFEL. The touch sensing layer TSU includes a first touch insulating layer TINS1, first connection electrodes BE1, a second touch insulating layer TINS2, the driving electrodes TE, the sensing electrodes RE, and a third touch insulating layer TINS3.

The first touch insulating layer TINS1 may be placed on the encapsulation layer TFEL. The first touch insulating layer TINS1 may have insulating properties and optical features. The first touch insulating layer TINS1 may include at least one inorganic film. For example, the first touch insulating layer TINS1 may be formed as a silicon nitride layer, a silicon oxynitride layer, a silicon oxide layer, a titanium oxide layer, or an aluminum oxide layer. Optionally, the first touch insulating layer TINS1 may be eliminated.

A plurality of first bridge electrodes BE1 may be disposed on the first touch insulating layer TINS1. The first bridge electrodes BE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second touch insulating layer TINS2 may be placed on the first bridge electrodes BE1 and the first touch insulating layer TINS1. The second touch insulating layer TINS2 may cover the first bridge electrodes BE1. The second touch insulating layer TINS2 may be an inorganic layer including at least one selected from the group consisting of: a silicon nitride layer, a silicon oxynitride layer, a silicon oxide layer, a titanium oxide layer and an aluminum oxide layer.

The plurality of driving electrodes TE and the plurality of sensing electrodes RE may be disposed on the second touch insulation layer TINS2. In addition to the driving electrodes TE and the sensing electrodes RE, the dummy patterns DE, the first touch driving lines TL1, the second touch driving lines TL2 and the touch sensing lines RL shown in FIG. 3 may be disposed on the second touch insulating film TINS1. The driving electrodes TE and the sensing electrodes RE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The driving electrodes TE and the sensing electrodes RE may overlap with the first bridge electrodes BE1 in the third direction DR3. The driving electrodes TE may be connected to the first bridge electrodes BE1 through touch contact holes TCNT1 penetrating through the first touch insulating layer TINS1.

The third touch insulating layer TINS3 may be placed over the driving electrodes TE, the sensing electrodes RE, and the second touch insulating layer TINS2. The third touch insulating layer TINS3 may have insulating properties and optical features. The third touch insulating layer TINS3 may provide a flat surface over the driving electrodes TE, the sensing electrodes RE and the first bridge electrodes BE1 having different heights. The third touch insulating layer TINS3 may be made of an organic layer such as an acryl resin, an epoxy resin, a phenolic resin, a polyamide resin and a polyimide resin.

A first light-blocking layer BM1 may be placed on the third touch insulating layer TINS3 of the touch sensing layer TSU. The first light-blocking layer BM1 may include a light-absorbing material. For example, the first light-blocking layer BM1 may include an inorganic black pigment or an organic black pigment. The inorganic black pigment may be, but is not necessarily limited to, carbon black, and the organic black pigment may include, but is not necessarily limited to, at least one of lactam black, perylene black, and aniline black.

The first light-blocking layer BM1 may overlap with the driving electrodes TE and the sensing electrodes RE in the thickness direction of the substrate, and may include a plurality of openings OPT1, OPT2, OPT3 and OPT4 in line with the pixel electrodes 171. For example, the first opening OPT1 may be in line with the pixel electrode 171 of the first emission area EA1, the second opening OPT2 may be in line with the pixel electrode 171 of the second emission area EA2, and the third opening OPT3 may be in line with the pixel electrode 171 of the third emission area EA3. The area or size of each of the openings OPT1, OPT2 and OPT3 may be larger than the area or size of the respective pixel electrodes 171. In addition, the area or size of each of the opening OPT1, OPT2 and OPT3 may be larger than that of the open areas of the pixel-defining layer 190. The lights emitted from the light-emitting elements LEL may be recognized by the user not only from the front but also from the sides of the display device 10.

The first light-blocking layer BM1 may have a width sufficient to completely cover the driving electrodes TE and the sensing electrodes RE. The first light-blocking layer BM1 can prevent light incident from the outside from being reflected by the driving electrodes TE or the sensing electrodes RE.

The color filters CF1, CF2 and CF3 may be disposed on the first light-blocking layer BM and the third insulating layer TINS3. The color filters CF1, CF2 and CF3 may be associated with the emission areas EA1, EA2 and EA3, respectively. For example, the first color filter CF1 may be in line with the first emission area EA1, the second color filter CF2 may be in line with the second emission area EA2, and the third color filter CF3 may be in line with the third emission area EA3. The color filters CF1, CF2 and CF3 may be associated with the openings OPT1, OPT2 and OPT3 of the first light-blocking layer BM1. For example, the first color filter CF1 may be in line with the first opening OPT1, the second color filter CF2 may be in line with the second opening OPT2, and the third color filter CF3 may be in line with the third opening OPT3.

Each of the color filters CF1, CF2 and CF3 may cover adjacent parts of the first light-blocking layer BM1.

Passivation layers PSV1 and PSV2 may be disposed over the first light-blocking layer BM1 and the color filter layer CFL. The passivation layers PSV1 and PSV2 may be disposed throughout the display area DA to provide a flat upper surface of the display panel 100. The passivation layers PSV1 and PSV2 may include a first passivation layer PSV1 disposed on the color filter layer CFL and the first light-blocking layer BM1, and a second passivation layer PSV2 disposed on the first passivation layer PSV1. The passivation layers PSV1 and PSV2 are made up of multiple layers and may provide a flat surface over the color filter layer CFL and the first light-blocking layer BM1 having different heights.

The passivation layers PSV1 and PSV2 may be a colorless light-transmitting layer having no color in the visible light range. For example, the passivation layers PSV1 and PSV2 may include a colorless light-transmitting organic material such as an acryl-based resin.

An overcoat layer OC may be placed on the passivation layers PSV1 and PSV2. The overcoat layer OC may be extended throughout the entire display area DPA, thereby providing the flat upper surface of the display panel 100. The overcoat layer OC may be a colorless light-transmitting layer having no color in the visible light band. For example, the overcoat layer OC may include a colorless light-transmitting organic material such as an acryl resin.

The display device 10, according to this embodiment, includes the color filter layer CFL, so that a portion of light entering from the outside of the display device 10 can be absorbed, to reduce reflected light due to external light. Accordingly, the color filter layer CFL can prevent distortion of colors due to the reflection of external light. In addition, since no separate polarizing plate is required to reduce the reflection of external light, the light emission efficiency of the display device 10 can be improved.

Incidentally, in the off-state of the display device 10 when no image is displayed, an asymmetrical color spreading (or asymmetrical color separation) phenomenon may occur, i.e., a color looks different between one end of the reflected light reflected in the display device 10 and the opposite end. For example, when the pixel electrode 171 of the light-emitting element LEL is formed flat, light may be reflected asymmetrically off the pixel electrode 171 due to the height differences of the organic layer placed under the pixel electrode 171. As a result, the asymmetric color spreading phenomenon may occur.

Thus, a versatile light-emitting display device suitable for phones, tablets, TVs, vehicle CIDs, wearables, and more, is provided. Embodiments may focus on an OLED implementation among several emissive display types. The panel architecture may include a main and subsidiary area, and a stacked structure including a display layer with TFTs and emissive elements, an encapsulation stack, a touch sensing layer, and a color filter layer positioned above. The touch system and color filter layer may be used to reduce reflections from metal lines and electrodes.

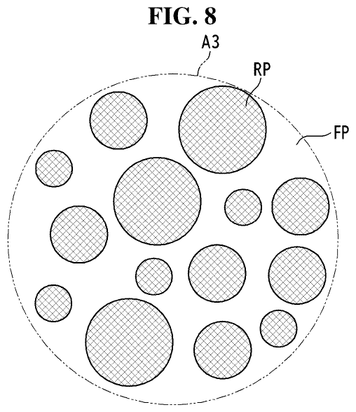

Hereinafter, a structure for reducing or preventing such asymmetric color spreading phenomenon will be described in detail in conjunction with FIGS. 7 and 8.

FIG. 7 is an enlarged, plan view showing in detail an example of area A2 of FIG. 6. FIG. 8 is an enlarged plan view showing recess portions RP and a flat portion FP in an emission area of area A3 according to the embodiment. To the extent that an element is not described in detail with respect to this figure, it may be understood that the element is at least similar to a corresponding element that has been described elsewhere within the present disclosure.

Referring to FIGS. 7 and 8, the upper surface of the second organic layer 180 may include a plurality of first recessed portions RP1 that are concave, and a plurality of first flat portions FP1 positioned between the plurality of first recessed portions RP1.

The plurality of first recessed portions RP1 may be formed throughout the upper surface of the second organic layer 180 and may be disposed seemingly randomly when viewed from the top. The first recessed portions RP1 may have a circular or elliptical shape when viewed from the top.

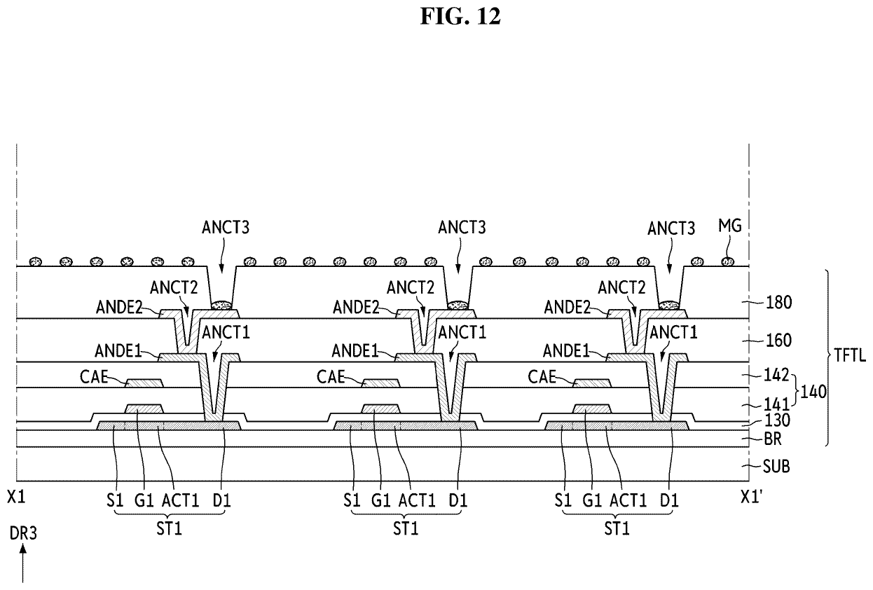

The maximum widths of the first recessed portions RP1 may be different from one another, but may be in a range of 60 nm or less. The maximum width of each of the first recessed portions RP1 may be determined based on the size of the respective metal grains MG (see FIG. 12) corresponding to the positions of the first recessed portions RP1, which are formed during the fabrication process. For example, if the size of a metal grain MG (see FIG. 12) formed during the fabricating process is 10 nm, the width of a first recessed portion RP1 formed on the second organic layer 180 at substantially the same position as the metal grain MG (see FIG. 12) may be 10 nm.

The first flat portions FP1 refer to flat portions disposed between the plurality of first recessed portions RP1. The first flat portions FP1 may be parallel to the upper surface of the substrate SUB. The width of the first flat portions FP1 may be defined as the minimum distance between adjacent first recessed portions RP1. The width of the first flat portions FP1 may be determined based on the spacing between the metal grains MG (see FIG. 12) formed during the fabrication process.

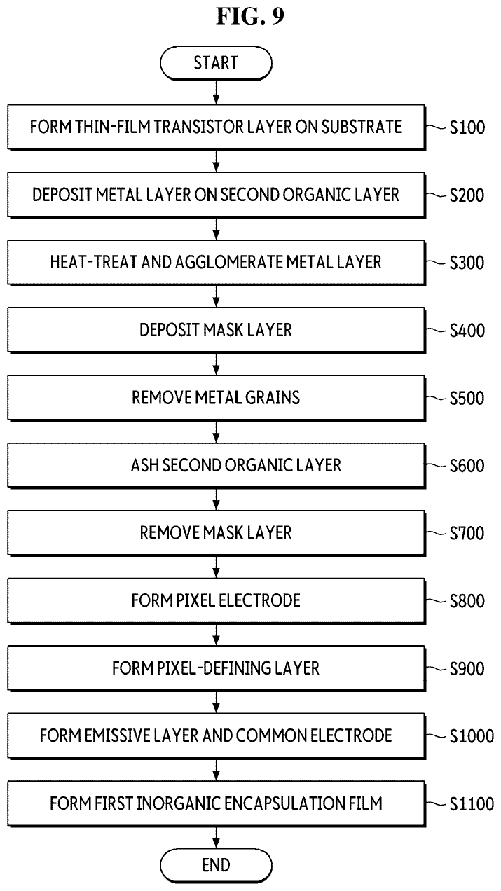

The width of the first recessed portions RP1 and the first flat portions FP1 will be described later in conjunction with FIGS. 9 to 20.

The pixel electrode 171 and the pixel-defining layer 190 may be placed on the second organic layer 180. The lower surfaces of the pixel electrode 171 and the pixel-defining layer 190 may include a plurality of first recessed portions RP1 that is concave, and a first flat portion FP1 disposed between the plurality of first recessed portions RP1.

The upper surface of the pixel electrode 171 may include a plurality of second recessed portions RP1 in line with the plurality of first recessed portions RP1 in the thickness direction of the substrate, and a second flat portion FP2 disposed between the plurality of second recessed portions RP2. The width of each of the second recessed portions RP2 may be substantially equal to the width of the respective first recessed portions RP1. The second flat portions FP2 may overlap with the first flat portions FP1 in the thickness direction of the substrate, and the second flat portions FP2 may be parallel to the upper surface of the substrate SUB. For example, the upper surface of the pixel electrode 171 may have the second recessed portions RP2 that are concave.

When light is incident from the outside and reflected, the reflected light may be scattered by the second recessed portions RP2 of the pixel electrode 171. As the second recessed portions RP2 scatters the reflected light, the phenomenon of asymmetric color spreading (or asymmetric color separation) of the reflected light can be prevented.

If the area of the second recessed portions RP2 disposed in each of the emission areas is 75% or more of the area of the emission areas, it is possible to effectively prevent the phenomenon of asymmetric color spreading (or asymmetric color separation) of reflected light.

The lower surface of the pixel-defining layer 190 may include a plurality of first recessed portions RP1 that are concave, and a first flat portion FP1 positioned between the first recessed portions RP1.

Since the pixel-defining layer 190 is thicker than the pixel electrode 171, the upper surface of the pixel-defining layer 190 might not include recessed portions that are concave, such as the second recessed portions RP2 on the upper surface of the pixel electrode 171. For example, the upper surface of the pixel-defining layer 190 may be parallel to the substrate SUB.

The emissive layer 172 may be disposed on the pixel electrode 171. The lower surface of the emissive layer 172 may include a plurality of second recessed portions RP2 that are concave, and a second flat portion FP2 positioned between the second recessed portions RP2.

The upper surface of the emissive layer 172 may include a plurality of third recessed portions RP3 in line with the plurality of second recessed portions RP2 in the thickness direction of the substrate, and a third flat portion FP3 disposed between the plurality of third recessed portions RP3. The width of the third recessed portions RP3 may be substantially equal to the widths of the respective first and second recessed portions RP1 and RP2. The third flat portions FP3 may overlap with the first and second flat portions FP1 and FP2 in the thickness direction of the substrate, and the third flat portions FP3 may be parallel to the upper surface of the substrate SUB. For example, the upper surface of the emissive layer 172 may have the third recessed portions RP3 that are concave.

The common electrode 173 may be disposed on the pixel-defining layer 190 and the emissive layer 172. The common electrode 173 may cover the side surfaces and the upper surface of the pixel-defining layer 190. The common electrode 173 disposed on the pixel-defining layer 190 in the thickness direction of the substrate may include an upper surface and a lower surface parallel to the substrate SUB without recessed portions.

Incidentally, the lower surface of the common electrode 173 overlapping with the emissive layer 172 in the thickness direction of the substrate may include a plurality of third recessed portions RP3 that are concave, and a third flat portion FP3 disposed between the plurality of third recessed portions RP3.

The upper surface of the common electrode 173 overlapping with the emissive layer 172 in the thickness direction of the substrate may include a plurality of fourth recessed portions RP4 in line with the first to third recessed portions RP1, RP2 and RP3 in the thickness direction of the substrate, and a fourth flat portion FP4 disposed between the plurality of fourth recessed portions RP4. The width of the fourth recessed portions RP4 may be substantially equal to the widths of the respective first to third recessed portions RP1, RP2 and RP3. The fourth flat portions FP4 may overlap with the first to third flat portions FP1, FP2 and FP3 in the thickness direction of the substrate, and the fourth flat portions FP4 may be parallel to the upper surface of the substrate SUB. For example, the upper surface of the common electrode 173 overlapping with the emissive layer 172 in the thickness direction of the substrate may include fourth recessed portions RP4 that are concave.

The first inorganic encapsulation film TFE1 may be disposed on the common electrode 171. The first inorganic encapsulation film TFE1 disposed on the pixel-defining layer 190 in the thickness direction of the substrate may include an upper surface and a lower surface parallel to the substrate SUB without recessed portions.

Incidentally, the lower surface of the first inorganic encapsulation film TFE1 overlapping with the emissive layer 172 in the thickness direction of the substrate may include a plurality of fourth recessed portions RP4 that are concave, and a fourth flat portion FP4 disposed between the plurality of fourth recessed portions RP4.

The upper surface of the first inorganic encapsulation film TFE1 overlapping with the emissive layer 172 in the thickness direction of the substrate may include a plurality of fifth recessed portions RP5 in line with the first to fourth recessed portions RP1, RP2, RP3 and RP4 in the thickness direction of the substrate, and a fifth flat portion FP5 disposed between the plurality of fifth recessed portions RP5. The width of the fifth recessed portions RP5 may be substantially equal to the widths of the respective first to fourth recessed portions RP1, RP2, RP3 and RP4. The fifth flat portions FP5 may overlap with the first to fourth flat portions FP1, FP2, FP3 and FP4 in the thickness direction of the substrate, and the fifth flat portions FP5 may be parallel to the upper surface of the substrate SUB. For example, the upper surface of the first inorganic encapsulation film TFE1 overlapping with the emissive layer 172 in the thickness direction of the substrate may include fifth recessed portions RP5 concave.

The organic encapsulation film TFE2 may be disposed on the first inorganic encapsulation film TFE1. Since the organic encapsulation film TFE2 is thicker than the first inorganic encapsulation film TFE1, the unevenness caused by the recessed portions RP may be flattened.

Thus, embodiments of the present disclosure may provide a device having a randomly distributed field of nanoscale first recessed portions on the second organic layer, each no wider than about 60 nm, with flat portions between them that are set by the spacing of metal grains formed during fabrication. The pixel electrode is deposited so that second recessed portions align with and match the widths of those first recesses. These features may scatter incident external light and suppress asymmetric color spreading, which is most effective when the recessed-area coverage in each emission area is at least 75 percent. The same topography propagates upward through the emissive layer as third recesses and into the common electrode and first inorganic encapsulation film as fourth and fifth recesses, while the pixel-defining layer's top remains flat and the thicker organic encapsulation above ultimately smooths the residual unevenness.

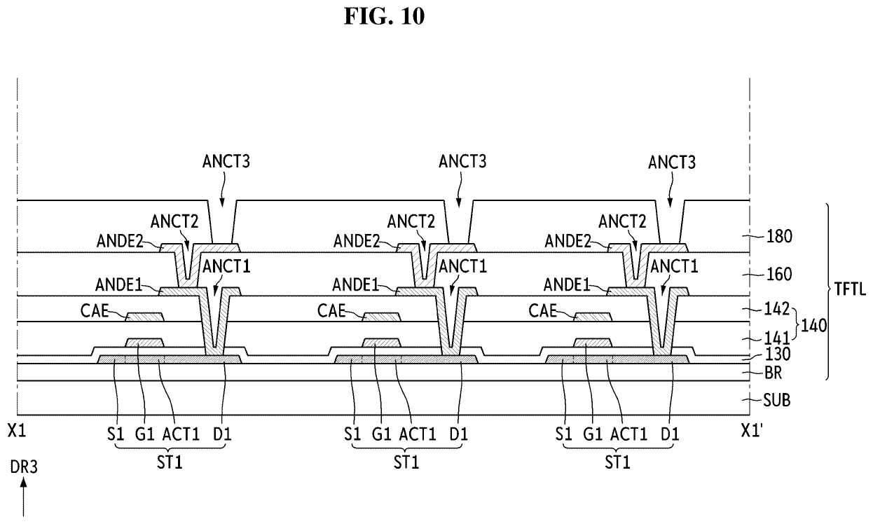

FIG. 9 is a flowchart for illustrating processing steps of fabricating a display device according to an embodiment of the present disclosure. FIGS. 10 to 19 are cross-sectional views showing processing steps of fabricating a display device according to an embodiment of the present disclosure.

First, a thin-film transistor layer TFTL is formed on a substrate SUB (step S100 of FIG. 9).

Referring to FIG. 10, a barrier layer BR is formed on the substrate SUB, and an active layer ACT1, a source electrode S1 and a drain electrode D1 of each of a plurality of thin-film transistors ST1 are formed on the barrier layer BR.

A gate insulator 130 may be formed on the active layer ACT1, the source electrode S1 and the drain electrode D1 of the thin-film transistor ST1.

The gate electrode G1 may be formed on the gate insulator 130, and the gate electrode G1 may overlap with the active layer ACT1 in the third direction DR3.

The first interlayer dielectric layer 141 may be formed on the gate electrode G1 of the thin-film transistor ST1 and the gate insulator 130.

The capacitor electrode CAE may be formed on the first interlayer dielectric layer 141. The capacitor electrode CAE may overlap the gate electrode G1 of the thin-film transistors ST1 in the third direction DR3.

A second interlayer dielectric layer 142 may be formed on the capacitor electrode CAE and the first interlayer dielectric layer 141.

The first connection contact hole ANCT1 exposing a portion of the drain electrode D1 of the thin-film transistor ST1 is formed in the gate insulator 130, the first interlayer dielectric layer 141 and the second interlayer dielectric layer 142.

The first anode connection electrode ANDE1 may be formed on the second interlayer dielectric layer 142, and the first anode connection electrode ANDE1 may be connected to the drain electrode D1 of the thin-film transistor ST1 through the first connection contact hole ANCT1.

The first organic layer 160 may be formed on the first anode connection electrode ANDE1 for providing a flat surface over the thin-film transistor ST1 having difference heights. A second connection contact hole ANCT2 is formed in the first organic layer 160 to penetrate the first organic layer 160 and expose a part of the first anode connection electrode ANDE1.

The second anode connection electrode ANDE2 may be formed on the first organic layer 160, and the second anode connection electrode ANDE2 may be connected to the first anode connection electrode ANDE1 through the second connection contact hole ANCT2.

The second organic layer 180 is formed over the second anode connection electrode ANDE2. A third connection contact hole ANCT3 is formed in the second organic layer 180 to penetrate the second organic layer 180 and expose a part of the second anode connection electrode ANDE2.

Second, a metal layer ML is deposited on the second organic layer 180 (step S200 of FIG. 9).

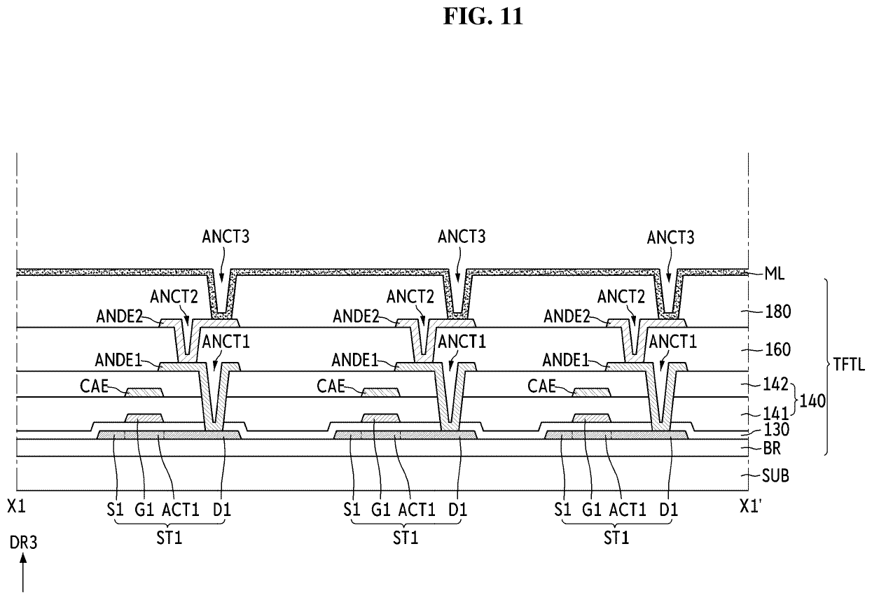

Referring to FIG. 11, the deposited metal layer ML may be disposed throughout the entire second organic layer 180 along the surface of the second organic layer 180. The metal layer ML may include silver (Ag), and the thickness of the metal layer ML may range from 2.5 nm to 5 nm.

Third, the metal layer ML is heat-treated to form a plurality of metal grains MG on the second organic layer 180 (step S300 of FIG. 9).

Referring to FIG. 12, after being heat-treated, the metal layer ML may be agglomerated to form a plurality of metal grains MG on the second organic layer 180.

As the metal layer ML contains silver (Ag), after being heat-treated at a temperature of approximately 250 °C for approximately one hour in a high-concentration nitrogen atmosphere, the metal layer ML may be uniformly oxidized in the high-concentration nitrogen atmosphere to form silver oxide (Ag₂O). Since the decomposition temperature of silver oxide (Ag₂O) of the metal layer ML is 200 °C or higher, it may be decomposed at 250 °C which is a heat treatment condition. The decomposed metal may form the metal grains MG through agglomeration. The metal grains MG may have different sizes.

TABLE 1

| | Thickness of Metal Layer | | |
|---|---|---|---|
| | 2.5 nm | 5 nm | 10 nm |
| Metal Grain Size | 20 nm or less | 30 nm to 60 nm | 200 nm or more |

Referring to Table 1, the size of the metal grains MG may vary depending on the thickness of the metal layer ML. The thinner the metal layer ML is, the smaller the size of the metal grains MG, and the thicker the metal layer ML is, the larger the size of the metal grains MG. For example, when the thickness of the metal layer ML is 2.5 nm, the size of the metal grains MG may be approximately 20 nm or less. When the thickness of the metal layer ML is 5 nm, the size of the metal grains MG may be 30 nm to 60 nm. When the thickness of the metal layer ML is 10 nm, the size of the metal grains MG may be 200 nm or more.

The width of the recessed portions RP may be substantially equal to the size of the respective metal grains MG. For example, if the size of a metal grain MG is 20 nm, the width of the respective recessed portion RP may be 20 nm.

If the sizes of the metal grains MG and the recessed portions RP are greater than 60 nm, the scattering of the reflected external light may be reduced, such that the phenomenon of asymmetric color spreading (or asymmetric color separation) of the reflected light might not be prevented.

In addition, since the metal grains MG are randomly disposed, the spacing between adjacent metal grains MG may be different. It should be noted, however, that as the size of the metal grains MG increases, the maximum spacing between adjacent metal grains MG may be increased.

Fourth, a mask layer MK is deposited (step S400 in FIG. 9).

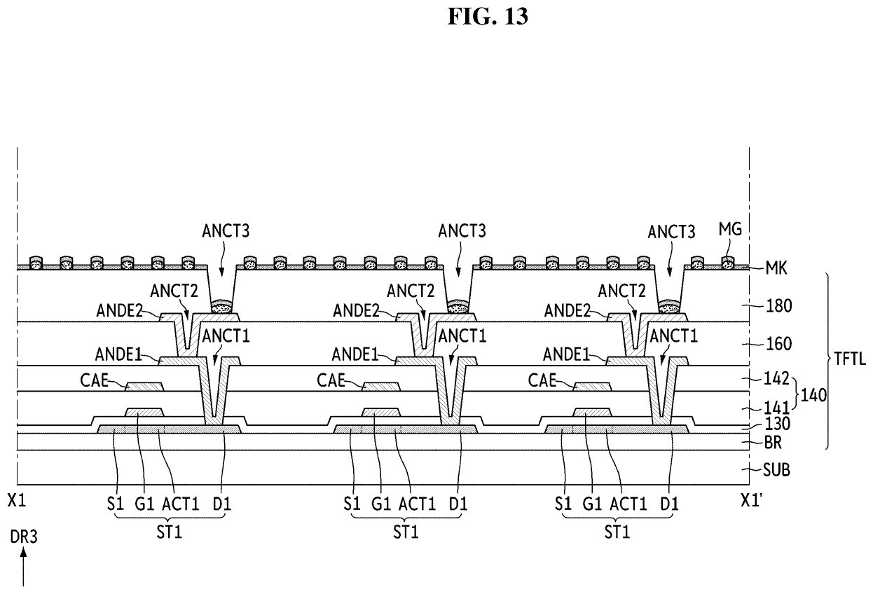

Referring to FIG. 13, the mask layer MK may be deposited on the metal grains MG and the second organic layer 180.

The second organic layer 180 may include portions where the metal grains MG are disposed, and portions where the metal grains MG are not disposed. The mask layer MK may be positioned on the surface of the metal grains MG and not on the second organic layer 180 in the portions where the metal grains MG are positioned. The mask layer MK may be positioned on the upper surface of the second organic layer 180 in the portions where the metal grains MG are not disposed.

The mask layer MK disposed on the upper surface of the second organic layer 180 may work as a mask after the metal grains MG have been removed. It is important that the mask layer MK disposed on the upper surface of the second organic layer 180 is uniformly maintained without being damaged in the process of removing the metal grains MG. To this end, the mask layer MK is preferably formed thinly to have a thickness of 8 nm or less. If the mask layer MK is thicker than 8 nm, it may adhere to nearby metal grains MG. When this happens, during the process of removing the metal grains MG, the mask layer MK disposed on the upper surface of the second organic layer 180 may be removed together with the mask layer MK disposed on the upper surfaces of the metal grains MG, and accordingly it cannot work as a mask.

The mask layer MK may include, but is not necessarily limited to, a transparent conductive oxide (TCO), such as ITO (indium tin oxide) and IZO (indium zinc oxide).

Fifth, the metal grains MG are removed (step S500 of FIG. 9).

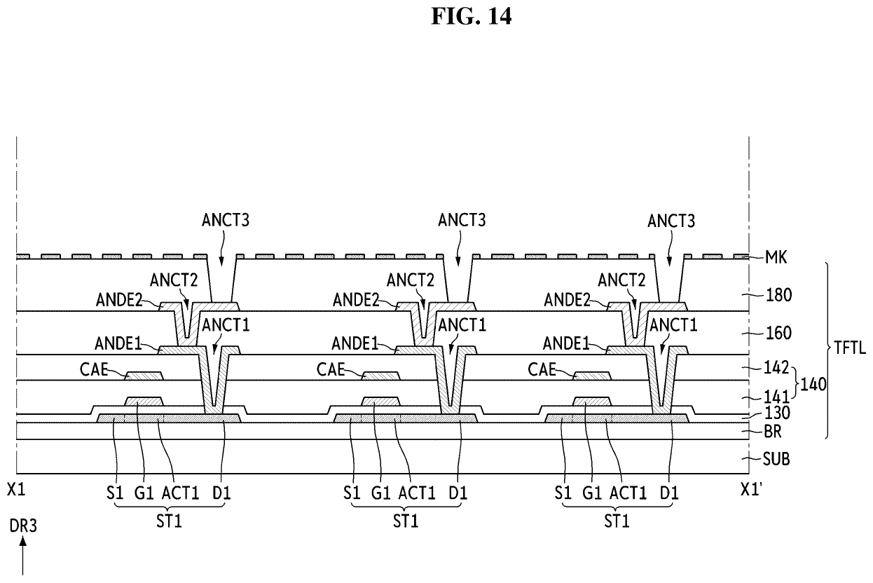

Referring to FIG. 14, the metal grains MG may be removed by a lift-off process. The solution used to remove the metal grains MG may be, but is not necessarily limited to, an acid solution containing sulfuric acid and nitric acid.

The mask layer MK deposited on the metal grains MG may be removed together with the metal grains MG by the lift-off process, leaving only the mask layer MK disposed on the upper surface of the second organic layer 180.

Sixth, the second organic layer 180 is ashed (step S600 of FIG. 9).

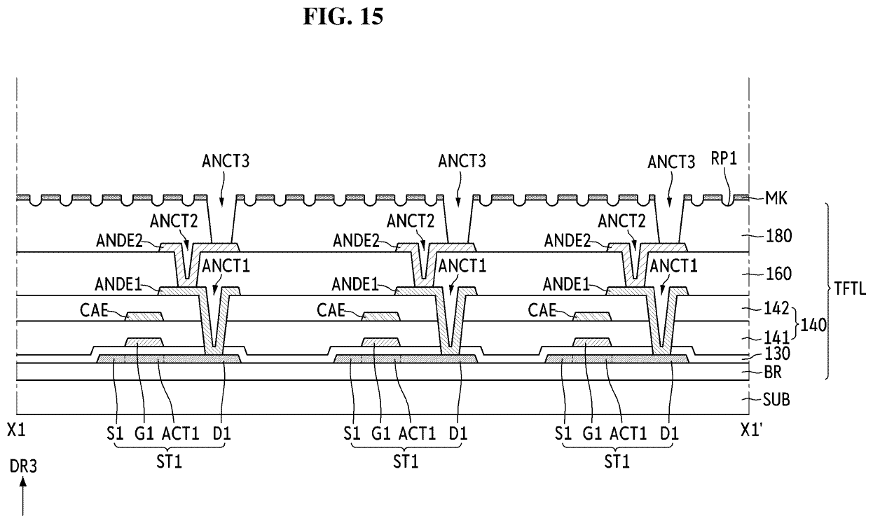

Referring to FIG. 15, portions of the second organic layer 180 that is exposed and not covered by the mask layer MK may be ashed using oxygen plasma, etc. As the exposed portions of the second organic layer 180 is ashed, a plurality of first recessed portions RP1 in a concave shape may be formed. For example, each of the plurality of first recessed portions RP1 formed on the upper surface of the second organic layer 180 may be formed at the positions of the respective metal grains MG. Accordingly, the width of each of the first recessed portions RP1 may be substantially equal to the width of the respective metal grains MG.

The first recessed portions RP1 may have a cross-sectional shape of a semicircle or a part of a circle (e.g., an arc), and the depth of the first recessed portions RP1 may be controlled by the ashing time. For example, as the ashing time increases, the depth of the recessed portions may increase.

Seventh, the mask layer MK is removed (step S700 in FIG. 9).

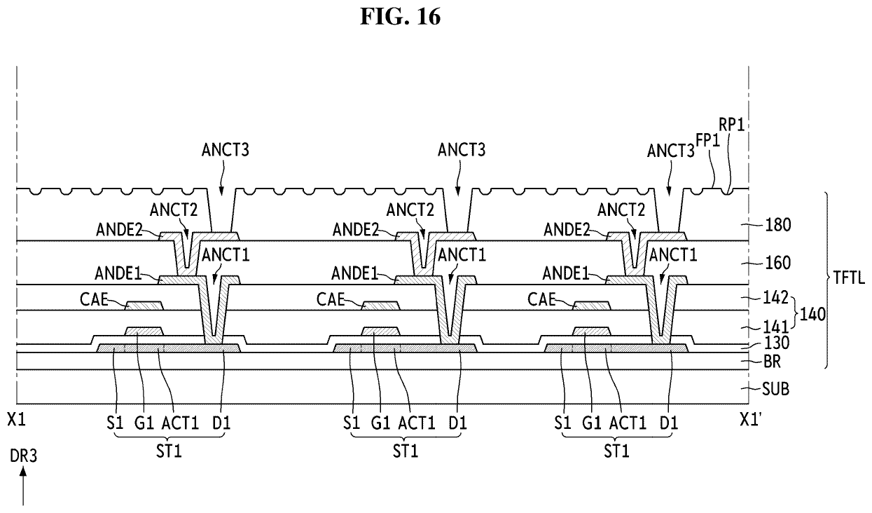

Referring to FIG. 16, after the first recessed portions RP1 of the second organic layer 180 has been formed, the mask layer MK may be removed. In doing so, it may be important to remove the mask layer MK without damaging the second organic layer 180. Therefore, in removing the mask layer MK, it is desired to use a solution with a selectivity for the mask layer MK of 100% so that only the mask layer MK is etched without etching the second organic layer 180.

In removing the mask layer MK, the second organic layer 180 might not be damaged and only the mask layer MK may be removed. If the mask layer MK is a transparent conductive oxide, it may be removed using an acid solution. For example, the acid solution may be, but is not necessarily limited to, phosphoric acid, nitric acid, or acetic acid.

After the mask layer MK has been removed, the second organic layer 180 may include a plurality of first recessed portions RP1, and a plurality of first flat portion FP1 positioned between the first recessed portions RP1. The first flat portions FP1 may have a flat shape compared to the first recessed portions RP1 because they are not ashed. For example, the inclination of the first flat portions FP1 may be approximately 1° or less. The upper surfaces of the first flat portions FP1 may be substantially parallel to the upper surface of the substrate SUB.

Eighth, a pixel electrode 171 is formed on the second organic layer 180 (step S800 of FIG. 9).

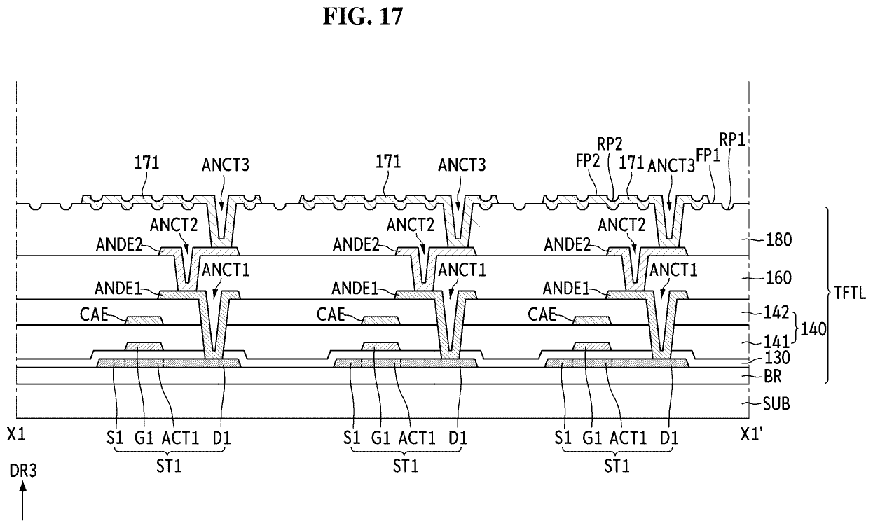

Referring to FIG. 17, a plurality of pixel electrodes 171 is formed on the second organic layer 180 on which the plurality of first recessed portions RP1 is formed. The plurality of pixel electrodes 171 may overlap with the thin-film transistors ST1 in the thickness direction of the substrate SUB, respectively. The pixel electrodes 171 may be connected to the second anode connection electrode ANDE2 through third connection contact holes ANCT3 penetrating the second organic layer 180.

The first recessed portions RP1 formed in the second organic layer 180 may be filled with the pixel electrodes 171. On the upper surfaces of the pixel electrodes 171, a plurality of second recessed portions RP2 may be formed at positions in line with the plurality of first recessed portions RP1 of the second organic layer 180 in the thickness direction of the substrate SUB. The width of each of the second recessed portions RP2 may be substantially equal to the width of the respective first recessed portions RP1. The second flat portions FP2 positioned between the second recessed portions RP2 may overlap with the first flat portions FP1 in the thickness direction of the substrate SUB. The second flat portions FP2 may be substantially parallel to the upper surface of the substrate SUB.

The lower surface of the pixel electrodes 171 may have patterns that are concave, and the upper surface of the pixel electrodes 171 may have the second recessed portions RP2 that are concave.

When light is incident from the outside and reflected, the reflected lights may be randomly scattered by the second recessed portions RP2 of the pixel electrodes 171. As the plurality of second recessed portions RP2 randomly scatter the reflected light, it is possible to prevent the light from being asymmetrically reflected by the pixel electrode 171. In this manner, it is possible to prevent the phenomenon of asymmetric color spreading (or asymmetric color separation) of the reflected light.

If the second recessed portions RP2 are randomly formed on the plane and the area of the second recessed portions RP2 disposed in each of the emission areas is 75% or more of the area of the emission areas, it is possible to effectively prevent the phenomenon of asymmetric color spreading (or asymmetric color separation) of reflected light.

Ninth, a pixel-defining layer 190 is formed (step S900 of FIG. 9).

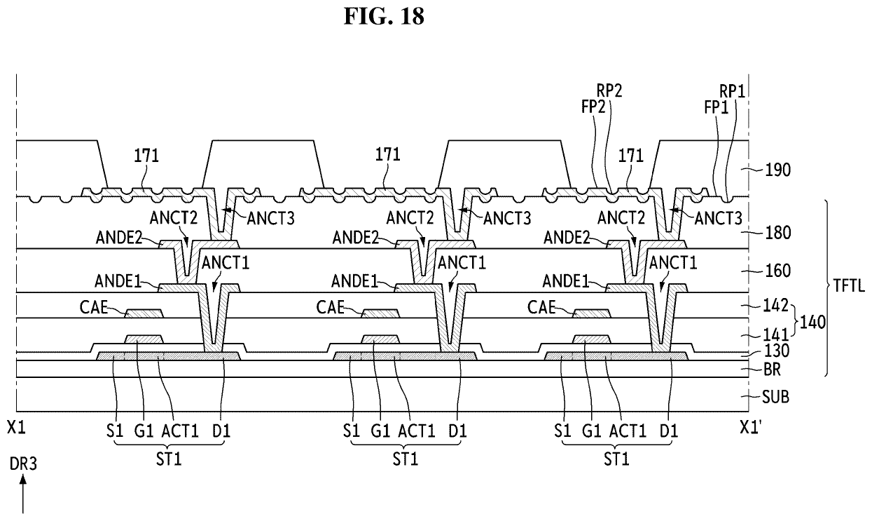

Referring to FIG. 18, in order to define a first emission area EA1, a second emission area EA2, a third emission area EA3 and a fourth emission area EA4, the pixel-defining layer 190 may be formed to partition the pixel electrodes 171 on the second organic layer 180. The pixel-defining layer 190 may be formed to cover the edges of the pixel electrode 171.

The first recessed portions RP1 on the upper surface of the second organic layer 180 that are exposed and not covered by the pixel electrodes 171 may be filled with the pixel-defining layer 190. The lower surface of the pixel-defining layer 190 may have patterns that are concave. Since the pixel-defining layer 190 is formed thickly, the upper surface of the pixel-defining layer 190 might not include recessed portions. For example, the upper surface of the pixel-defining layer 190 may be parallel to the upper surface of the substrate SUB.

Tenth, an emissive layer 172 and a common electrode 173 are formed (step S1000 of FIG. 9).

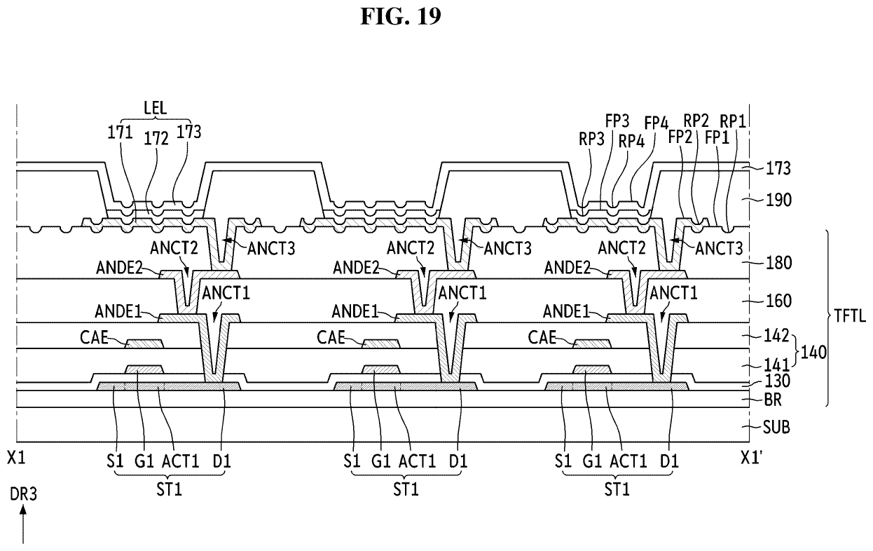

Referring to FIG. 19, the emissive layer 172 is formed on the respective pixel electrode 171. The second recessed portions RP2 disposed on the upper surfaces of the pixel electrodes 171 may be filled with emissive layers 172. On the upper surfaces of the emissive layers 172, a plurality of third recessed portions RP3 may be formed at positions in line with the second recessed portions RP2 of the pixel electrodes 171 in the thickness direction of the substrate SUB. The width of each of the plurality of third recessed portions RP3 may be substantially equal to the width of the respective first recessed portions RP1 and the respective second recessed portions RP2. Third flat portions FP3 positioned between the third recessed portions RP3 may overlap with the first flat portions FP1 and the second flat portions FP2 in the thickness direction of the substrate SUB. The third flat portions FP3 may be parallel to the upper surface of the substrate SUB.

The lower surfaces of the emissive layers 172 may have patterns that are concave, and the upper surfaces of the emissive layers 172 may have the third recessed portions RP3 that are concave.

The common electrode 173 is formed on the pixel-defining layer 190 and the emissive layer 172. The common electrode 173 may cover the side surfaces and the upper surface of the pixel-defining layer 190. The common electrode 173 overlapping the pixel-defining layer 190 in the thickness direction of the substrate SUB may include a flat upper surface and a lower surface without recessed portions. The third recessed portions RP3 of the emissive layers 172 may be filled with the common electrode 173 overlapping the emissive layers 172 in the thickness direction of the substrate SUB. A plurality of fourth recessed portions RP4 may be formed on the upper surface of the common electrode 173 at positions in line with the plurality of third recessed portions RP3 of the emissive layers 172 in the thickness direction of the substrate SUB. The width of each of the plurality of fourth recessed portions RP4 may be equal to the width of the respective first recessed portions RP1 to the respective third recessed portions RP3. The fourth flat portions FP4 positioned between the fourth recessed portions RP4 may overlap the first flat portions FP1 to third flat portions FP3 in the thickness direction of the substrate SUB. The fourth flat portions FP4 may be parallel to the upper surface of the substrate SUB.

The lower surface of the common electrode 173 may have patterns that are concave, and the upper surface of the common electrode 173 may have the fourth recessed portions RP4 that are concave.

Eleventh, the first inorganic encapsulation film TFEL is formed (step S1100 in FIG. 9).

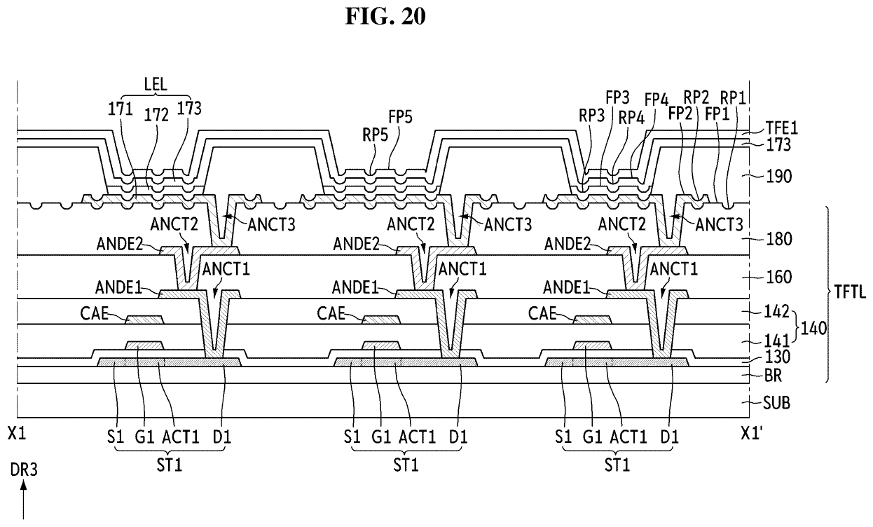

Referring to FIG. 20, a first inorganic encapsulation film TFEL is formed on the common electrode 173. The first inorganic encapsulation film TFE1 disposed on the pixel-defining layer 190 in the thickness direction of the substrate may include a flat upper surface and a flat lower surface without recessed portions. The fourth recessed portions RP4 of the common electrode 173 may be filled with the first inorganic encapsulation film TFE1 overlapping the emissive layers 172 in the thickness direction of the substrate SUB. On the upper surfaces of the first inorganic encapsulation film TFE1, a plurality of fifth recessed portions RP5 may be formed at positions in line with the plurality of fourth recessed portions RP4 of the common electrode 173 in the thickness direction of the substrate SUB. The width of each of the plurality of fifth recessed portions RP5 may be equal to the width of the respective first recessed portions RP1 to the respective fourth recessed portions RP4. The fifth flat portions FP5 may be parallel to the upper surface of the substrate SUB.

The lower surface of the first inorganic end film TFE1 may have patterns that are concave, and the upper surface of the first inorganic encapsulation film TFE1 may have the fifth recessed portions RP5 that are concave.

The display device according to the embodiment may be applied to a variety of electronic devices. An electronic device according to an embodiment includes the display device described above, and may further include a module or device having additional features in addition to the display device.

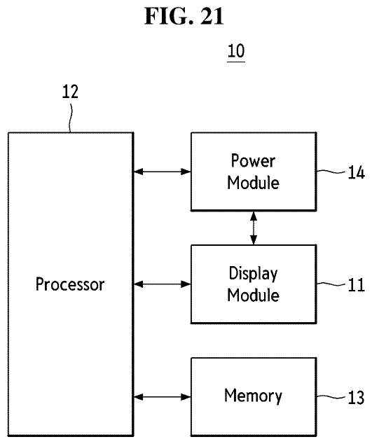

FIG. 21 is a block diagram of an electronic device according to an embodiment of the present disclosure.

Referring to FIG. 21, an electronic device 10, according to an embodiment of the present disclosure, may include a display module 11, a processor 12, a memory 13, and a power module 14.

The processor 12 may include at least one of: a central processing unit (CPU), an application processor (AP), a graphic processing unit (GPU), a communication processor (CP), an image signal processor (ISP), and a controller.

The memory 13 may store data information required for the operation of the processor 12 or the display module 11. When the processor 12 executes an application stored in the memory 13, an image data signal and/or an input control signal may be transmitted to the display module 11. The display module 11 may process the received signal and output image information through a display screen.

The power module 14 may include a power supply module such as a power adapter and a battery device, and a power conversion module that converts the power supplied by the power supply module to generate power required for the operation of the electronic device 10.

At least one of the elements of the electronic device 11 described above may be included in the display devices according to the embodiments described above. In addition, some of the individual modules functioning as a single module may be included in the display device while some others may be provided separately from the display device. For example, the display device may include the display module 11, and the processor 12, the memory 13 and the power module 14 may be implemented as other devices inside the electronic device 11 instead of the display device.

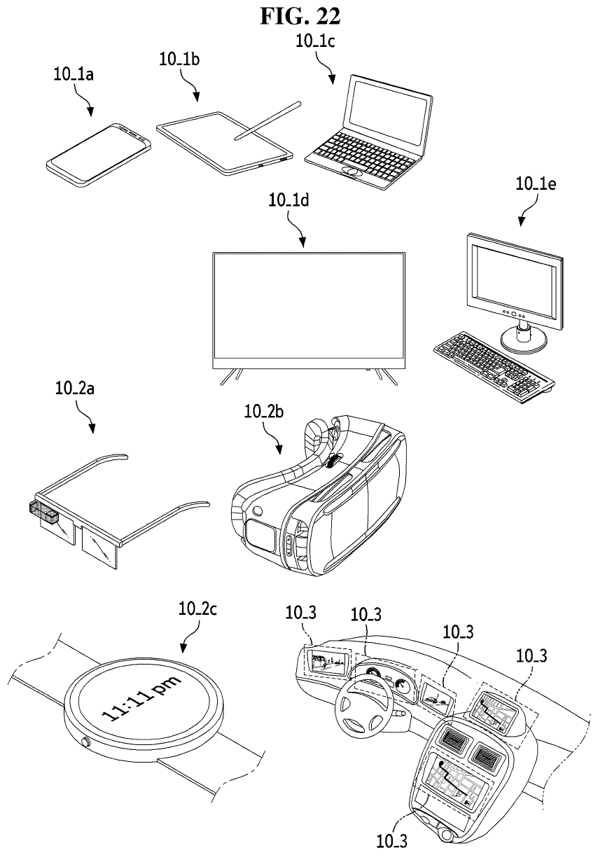

FIG. 22 is a view showing electronic devices according to a variety of embodiments of the present disclosure.

Referring to FIG. 22, a variety of electronic devices employing display devices according to embodiments may include not only image display electronic devices such as a smart phone 10_1a, a tablet computer 10_1b, a laptop/notebook computer 10_1c, a TV 10_1d and a computer monitor 10_1e, but also wearable electronic devices including display modules such as smart glasses 10_2a, a head-mounted display 10_2b and a smart watch 10_2c, and electronic devices for vehicles 10_3 including display modules such as a center information display (CID) placed on the dashboard, the center fascia and the dashboard of a vehicle, and a room mirror display.

While the present disclosure has been particularly shown and described with reference to embodiments thereof, it will be understood by those of ordinary skill in the art that various changes in form and detail may be made therein without departing from the spirit and scope of the present disclosure. The embodiments of the present disclosure described herein should be considered in a descriptive sense and not necessarily for purposes of limitation.

What is claimed is:

1. A display device, comprising:
a substrate;
a plurality of thin-film transistors disposed on the substrate;
an organic layer disposed on the plurality of thin-film transistors;
a plurality of light-emitting elements disposed on the organic layer and configured to emit light;
an encapsulation layer disposed on the plurality of light-emitting elements;
a color filter layer disposed on the encapsulation layer and configured to transmit light in a particular wavelength range,
wherein each of the plurality of light-emitting elements comprises:
a first electrode disposed on the organic layer;
an emissive layer disposed on the first electrode; and
a second electrode disposed on the emissive layer,
wherein an upper surface of the first electrode comprises a plurality of first recessed portions, and a first flat portion disposed between the first recessed portions,
wherein each of the plurality of first recessed portions has a concave shape with respect to the upper surface of the first electrode, and
wherein a width of each of the plurality of first recessed portions is equal to or less than 60 nm.

2. The display device of claim 1, wherein a plurality of second recessed portions is disposed on an entire upper surface of the organic layer, each of the plurality of second recessed portions has a concave shape with respect to the upper surface of the organic layer, and
wherein some of the plurality of second recessed portions overlap with the plurality of light-emitting elements, while the others do not overlap with the plurality of light-emitting elements.

3. The display device of claim 1, wherein a lower surface of the first electrode comprises a plurality of second recessed portions that is concave with respect to the lower surface of the first electrode, and a second flat portion is disposed between the plurality of second recessed portions.

4. The display device of claim 3, wherein each of the second recessed portions overlaps with a respective one of the first recessed portions in a thickness direction of the substrate, and
wherein a width of each of the second recessed portions is equal to a width of the respective one of the first recessed portions.

5. The display device of claim 1, wherein an upper surface of the emissive layer comprises a plurality of third recessed portions that are each concave with respect to the upper surface of the emissive layer, and a third flat portion that is disposed between the plurality of third recessed portions.

6. The display device of claim 5, wherein each of the third recessed portions overlaps with a respective one of the first recessed portions in a thickness direction of the substrate, and
wherein a width of each of the third recessed portions is equal to a width of the respective one of the first recessed portions.

7. The display device of claim 1, wherein an upper surface of the second electrode comprises a plurality of fourth recessed portions that each have a concave shape with respect to the upper surface of the second electrode, and a fourth flat portion is disposed between the plurality of fourth recessed portions.

8. The display device of claim 7, wherein each of the fourth recessed portions overlaps with a respective one of the first recessed portions in a thickness direction of the substrate, and
wherein a width of each of the fourth recessed portions is equal to a width of the respective one of the first recessed portions.

9. The display device of claim 1, wherein an upper surface of the encapsulation layer comprises a plurality of fifth recessed portions that has a concave shape with respect to the upper surface of the encapsulation layer, and a fifth flat portion is disposed between the plurality of fifth recessed portions.

10. The display device of claim 9, wherein each of the fifth recessed portions overlaps with a respective one of the fifth recessed portions in a thickness direction of the substrate, and
wherein a width of each of the fifth recessed portions is equal to a width of the respective one of the fifth recessed portions.

11. The display device of claim 1, wherein an area of the plurality of first recessed portions disposed in each of the plurality of light-emitting elements occupies 75% or more of an area of respective emission areas.

12. A method for fabricating a display device, the method comprising:
forming a plurality of thin-film transistors on a substrate, and forming an organic layer on the plurality of thin-film transistors;
depositing a metal layer entirely covering the organic layer on the organic layer;
heat-treating and agglomerating the metal layer to form a plurality of metal grains that are spaced apart from one another;
depositing a mask layer on the plurality of metal grains and the organic layer so as to cover the plurality of metal grains;
removing the plurality of metal grains and the mask layer positioned on the plurality of metal grains, leaving the mask layer positioned between the plurality of metal grains;
ashing the organic layer that is exposed and not covered by the mask layer to form a plurality of first recessed portions in an upper surface of the organic layer, and removing the mask layer, each of the plurality of first recessed portions having a concave shape with respect to the upper surface of the organic layer;
forming a plurality of pixel electrodes spaced apart from one another on the organic layer;
forming a pixel-defining layer covering an edge of each of the plurality of pixel electrodes;
forming an emissive layer on each of the plurality of pixel electrodes exposed without being covered by the pixel-defining layer, and forming a common electrode on the emissive layer and the pixel-defining layer; and
forming an encapsulation layer on the common electrode.

13. The method of claim 12, wherein the pixel electrodes are disposed on the first recessed portions of the organic layer, and
wherein an upper surface of each of the plurality of pixel electrodes comprises a plurality of second recessed portions, and a second flat portion is disposed between the plurality of second recessed portions, each of the plurality of second recessed portions having a concave shape with respect to the upper surface of the plurality of pixel electrodes.

14. The method of claim 13, wherein each of the second recessed portions overlaps with a respective one of the first recessed portions in a thickness direction of the substrate, and
wherein a width of each of the second recessed portions is equal to a width of the respective one of the first recessed portions.

15. The method of claim 12, wherein the metal layer and the metal grains include silver (Ag).

16. The method of claim 12, wherein a thickness of the metal layer ranges from 2.5 nm to 5 nm.

17. The method of claim 12, wherein the mask layer comprises conductive oxide, and
wherein a thickness of the mask layer is smaller than a size of the metal grains.

18. The method of claim 12, wherein a size of each of the plurality of first recessed portions is equal to the size of a respective one of the plurality of metal grains at a same position.

19. An electronic device, comprising:
a display module for displaying an image; and
a processor for transmitting an image data signal to the display module,
wherein the display module comprises:
a substrate;
a plurality of thin-film transistors disposed on the substrate;
an organic layer disposed on the plurality of thin-film transistors;
a plurality of light-emitting elements disposed on the organic layer and emitting light;
an encapsulation layer disposed on the plurality of light-emitting elements;
a color filter layer disposed on the encapsulation layer and configured to transmit light in a particular wavelength range,
wherein each of the plurality of light-emitting elements comprises:
a first electrode disposed on the organic layer;
an emissive layer disposed on the first electrode; and
a second electrode disposed on the emissive layer,
wherein an upper surface of the first electrode comprises a plurality of first recessed portions, and a first flat portion is disposed between the first recessed portions,
wherein each of the plurality of first recessed portions has a concave shape with respect to the upper surface of the first electrode, and
wherein a width of each of the plurality of first recessed portions is equal to or less than 60 nm.

20. The electronic device of claim 19, wherein a lower surface of the first electrode comprises a plurality of second recessed portions, and a second flat portion is disposed between the plurality of second recessed portions, each of the plurality of second recessed portions having a concave shape with respect to the lower surface of the first electrode.
